(19) United States
(12) Patent Application Publication
(10) Pub. No.: US 2017/0298198 A1
(43) Pub. Date: Oct. 19, 2017

(54) AROMATIC POLYAMIDE FILMS FOR SOLVENT RESISTANT FLEXIBLE SUBSTRATES

(71) Applicants: FRANK W. HARRIS, BOCA RATON, FL (US); DONG ZHANG, UNIONTOWN, OH (US); LIMIN SUN, COPLEY, OH (US); JIAOKAI JING, UNIONTOWN, OH (US); HIDEO UMEDA, KOBE-SHI (JP); JUN OKADA, KOBE-SHI (JP)

(72) Inventors: FRANK W. HARRIS, BOCA RATON, FL (US); DONG ZHANG, UNIONTOWN, OH (US); LIMIN SUN, COPLEY, OH (US); JIAOKAI JING, UNIONTOWN, OH (US); HIDEO UMEDA, KOBE-SHI (JP); JUN OKADA, KOBE-SHI (JP)

(73) Assignees: SUMITOMO BAKELITE CO., LTD., SHINAGAWA-KU (JP); AKRON POLYMER SYSTEMS, INC., AKRON, OH (US)

(21) Appl. No.: 15/636,281

(22) Filed: Jun. 28, 2017

Related U.S. Application Data
(63) Continuation of application No. 14/140,057, filed on Dec. 24, 2013.
(60) Provisional application No. 61/745,933, filed on Dec. 26, 2012.

(51) Int. Cl. C08J 5/18; H01L 51/00; C08G 69/32; C08G 69/42

(52) U.S. Cl. CPC C08J 5/18; C08G 69/42; H01L 51/0043; C08G 69/32; C08J 2377/00; C08J 2463/00; C08J 2377/10

(57) ABSTRACT

A process for manufacturing a display device, an optical device or an illuminating device includes casting a polyamide solution onto a base at temperature below 200° C. to obtain a film, heating the film on the base at temperature sufficient to make the film solvent resistant and obtain a polyamide film, forming on a surface of the polyamide film one of a display element, an optical element and an illumination element to form a display device, an optical device or an illumination device, and de-bonding the base from the display device, the optical device or the illuminating device. The polyamide solution comprises a solvent, an aromatic polyamide dissolved in the solvent, and a multifunctional epoxyde, where the aromatic polyamide comprises at least one functional group that reacts with an epoxy group, the aromatic polyamide comprises a first repeat unit of formula (I) and a second repeat unit of formula (II)

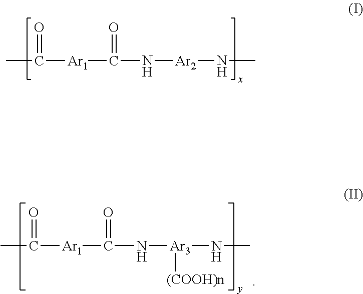

### CROSS-REFERENCE TO RELATED APPLICATION

The present application is a continuation of and claims the benefit of priority to U.S. application Ser. No. 14/140,057, filed Dec. 24, 2013, which is based upon and claims the benefit of priority to U.S. Provisional Application No. 61/745,933, filed Dec. 26, 2012. The entire contents of these applications are incorporated herein by reference.

### TECHNICAL FIELD

The disclosure relates to the manufacture of thermally and dimensionally stable transparent polymer films More particularly, the disclosure relates to the manufacture and use of aromatic polyamides, which have a rigid backbone with a glass transition temperature (Tg) higher than 300° C., yet are still soluble in conventional organic solvents without the need for the presence of inorganic salts. The polymer films can be prepared by solution casting, and cured at elevated temperatures. The cured films show a high optical transparency over a range of 400˜750 nm, (transmittance >80%), a low coefficient of thermal expansion (CTE <20 ppm/° C.), and good solvent resistance.

Furthermore, this disclosure, in one aspect, relates to a solution of polyamide including an aromatic polyamide, a solvent and optionally an epoxide. This disclosure, in another aspect, relates to a process of manufacturing the polyamide solution. This disclosure, in another aspect, relates to a process for manufacturing a display element, an optical element or an illumination element, including a step of forming a polyamide film using the polyamide solution.

### BACKGROUND

Organic Light Emitting Diode (OLED) displays were a $1.25 billion market in 2010, which is projected to grow annually at a rate of 25%. The high efficiency and high contrast ratio of OLED displays make them a suitable replacement for liquid crystal displays (LCDs) in the mobile phone display, digital camera, and global positioning system (GPS) market segments. These applications place a premium on high electrical efficiency, compact size, and robustness. This has increased the demand for active matrix OLEDs (AMOLEDs) which consume less power, have faster response times, and higher resolutions. AMOLED innovations that improve these properties will further accelerate AMOLED adoption into portable devices and expand the range of devices that use them. These performance factors are largely driven by the processing temperature of the electronics. AMOLEDs have a thin-film transistor (TFT) array structure which is deposited on the transparent substrate. Higher TFT deposition temperatures can dramatically improve the electrical efficiency of the display. Currently, glass plates are used as AMOLED substrates. They offer high processing temperatures (>500° C.) and good barrier properties, but are relatively thick, heavy, rigid, and are vulnerable to breaking, which reduces product design freedom and display robustness. Thus, there is a demand by portable device manufacturers for a lighter, thinner, and more robust replacement. Flexible substrate materials would also open new possibilities for product design, and enable lower cost roll-to-roll fabrication.

Many polymer thin films have excellent flexibility, transparency, are relatively inexpensive, and are lightweight. Polymer films are excellent candidates for substrates for flexible electronic devices, including flexible displays and flexible solar cell panels, which are currently under development. Compared to rigid substrates like glass, flexible substrates offer some potentially significant advantages in electronic devices, including:

a. Light weight (glass substrates represent about 98% of the total weight in a thin film solar cell).

b. Flexible (Easy to handle, low transportation costs, and/or more applications for both raw materials and products.)

c. Amenable to roll-to-roll manufacturing, which could greatly reduce the manufacturing costs.

To facilitate these inherent advantages of a polymeric substrate for the flexible display application, several issues must be addressed including:

a. Increasing the thermal stability;

b. Reducing the coefficient of thermal expansion (CTE);

c. Maintaining high transparency during high temperature processing; and,

d. Increasing the oxygen and moisture barrier properties. Currently, no pure polymer film can provide sufficient barrier properties. To achieve the target barrier property, an additional barrier layer must be applied.

Several polymer films have been evaluated as transparent flexible substrates, including: polyethylene terephthalate (PET), polyethylene naphthalate (PEN), polycarbonate, polyethersulfone (PES), cyclic olefin polymer (COP), polyarylates (PAR), polyimides (PI), and others. However, no one film can meet all the requirements. Currently, the industrial standard for this application is PEN film, which meets part of the requirements (Transmittance >80% between 400 nm˜750 nm, CTE <20 ppm/° C.), but has a limited use temperature (<200° C.). A transparent polymer film with a higher thermal stability (Tg >300° C.) and a lower CTE (<20 ppm/° C.) is desirable.

Conventional aromatic polyimides are well known for their excellent thermal and mechanical properties, but their films, which must be cast from their polyamic acid precursors, are usually dark yellow to orange. Some aromatic polyimides have been prepared that can be solution cast into films that are colorless in the visible region, but such films do not display the required low CTE (For example, F. Li. F. W. Harris, and S. Z. D. Cheng, Polymer, 37, 23, pp 5321 1996). The films are also not solvent resistant. Polyimide films based on part or all alicyclic monomers, such as those described in patents JP 2007-063417 and JP 2007-231224, and publication by A. S. Mathews et al (J. Appl. Polym. Sci., Vol. 102, 3316-3326, 2006), show improved transparency. Although Tgs of these polymers can be higher than 300° C., at these temperatures the polymers do not show sufficient thermal stability due to their aliphatic units.

Fiber reinforced polymer composite films, such as reported by H. Ito (Jap. J. Appl. Phys., 45, No. 5B, pp 4325, 2006), combine the dimensional stability of fiber glass in a polymer film, offering an alternative way to achieve a low CTE. However, in order to maintain a high transparency, the refractive indices of the matrix polymer and the fiber must be precisely matched, which greatly limits the choice of the matrix polymer within an organic silicon resin. By using nanoparticles as filler, the effect of lowering CTE is not significant (J M Liu, et al, J. SID, Vol. 19, No. 1, 2011)

Although most aromatic polyamides are poorly soluble in organic solvents and cannot be solution cast into films, a few polymers have been prepared that are soluble in polar aprotic solvents containing inorganic salts. Some of these have been investigated for use as flexible substrates. For example, JP 2009-79210A describes a thin film prepared from a fluorine containing aromatic polyamide that displays a very low CTE (<0 ppm/° C.), good transparency (T % >80 between 450˜700 mn), and excellent mechanical properties. However, the maximum thickness of films made from this polymer is 20 μm, because a dry-wet method where the salt is removed must be used for the film preparation. Most importantly, the film also displays poor resistance to strong organic solvents.

Aliphatic polyamides are known to react with epoxy resins in the melt and are commonly used as epoxy curing agents. However, due to their high melting temperatures and limited solubility aromatic polyamides are not used as curing agents.

### SUMMARY

This disclosure, viewed from one aspect, relates to a solution of polyamide comprising: an aromatic polyamide, wherein the aromatic polyamide comprises one or more functional groups that can react with an epoxy group.

This disclosure, viewed from another aspect, relates to a combination of the solution of polyamide according to this disclosure and an epoxide, wherein the solution of polyamide and the epoxide are separately packaged.

This disclosure, viewed from another aspect, relates to a process for manufacturing a solution of an aromatic polyamide comprising the steps of:

a) dissolving one or more aromatic diamines in a solvent,
where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.

This disclosure, viewed from another aspect, relates to a process for manufacturing a display element, an optical element or an illumination element, comprising the steps of:

a) dissolving one or more aromatic diamines in a solvent,
where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.

e) casting the resulting polyamide solution into a film onto a base at a temperature below approximately 200° C.;

f) heating the polyamide film on the base at a temperature that results is the film becoming solvent resistant; and

g) forming the display element, the optical element or the illumination element on the surface of the polyamide film.

This disclosure, viewed from another aspect, relates to a process for manufacturing a display element, an optical element or an illumination element, comprising the steps of:

a) casting a solution of an aromatic polyamide into a film onto a base at a temperature below approximately 200° C.;

b) heating the polyamide film on the base at a temperature that results is the film becoming solvent resistant; and

c) forming the display element, the optical element or the illumination element on the surface of polyamide film;

wherein the solution of an aromatic polyamide comprising an aromatic polyamide, a solvent, and a multifunctional epoxide,

wherein the aromatic polyamide comprises one or more functional groups that can react with an epoxy group.

This disclosure, viewed from another aspect, relates to a process for manufacturing a transparent, solvent resistant, dimensionally stable, aromatic polyamide film comprising the steps of:

a) forming a mixture of two or more aromatic diamines where at least one of the diamines contains one or more functional groups that can react with an epoxy group.

b) dissolving the aromatic diamine mixture in a polar solvent;

c) reacting the diamine mixture with at least one aromatic diacid dichloride, wherein hydrochloric acid and a polyamide solution is generated;

d) simultaneously removing the free hydrochloric acid by reaction with an acid trapping reagent;

e) adding a multifunctional epoxide;

f) casting the resulting polyamide solution into a film at a temperature below approximately 200° C.;

g) heating the polyamide film at a temperature that results is the film becoming solvent resistant.

The present disclosure, viewed from another aspect, is directed toward transparent films with CTEs less than 20 ppm/° C. prepared from aromatic copolyamides that are soluble in organic solvents and have Tgs greater than 300° C. The films are cast using solutions of the polyamides in N,N-dimethylacetamide (DMAc), N-methyl-2-pyrrolidinone (NMP), or other polar solvents. The present disclosure can be produced in the absence of an inorganic salt. It has been discovered that the films can be crosslinked in the solid state with multifunctional compounds containing epoxy groups, such that the optical and thermal properties of the polyamides do not change significantly during the curing process. It has also been discovered that the crosslinking process can be facilitated by the presence of a few free, pendant carboxyl groups along the polyamide backbones.

### BRIEF DESCRIPTION OF THE DRAWINGS

FIG. 1 is a schematic cross-sectional view showing an organic EL element 1 according to one embodiment.

FIG. 2 is a schematic flow of a manufacturing process of OLED element.

### DETAILED DESCRIPTION

The present disclosure, viewed from one aspect, is directed toward transparent films prepared from aromatic copolyamides. A polyamide is prepared via a condensation polymerization in a solvent, where the hydrochloric acid generated in the reaction is trapped by a reagent like propylene oxide (PrO). Colorless films can be prepared by casting procedures at a temperature below approximately 200° C. directly from the polymerization solutions. These films display low CTEs as cast and do not need to be subjected to stretching. By carefully manipulating the ratio of the monomers used to prepare the copolyamides, the Tgs of the resulting copolymers and the CTEs and optical properties of their solution cast films can be controlled. By adding a multifunctional compound containing epoxy groups to the polymer solution, the resulting film can be cured at a temperature between approximately 200° C. and approximately 250° C.

Viewed from one aspect, this disclosure relates to a solution of polyamide comprising: an aromatic polyamide and a solvent (hereinafter, referred also to as “the solution of the present disclosure”). The aromatic polyamide comprises one or more functional groups that can react with an epoxy group.

In one or plurality of embodiments of this disclosure, the solution of the present disclosure further comprises a multifunctional epoxide.

In one or plurality of embodiments of this disclosure, at least one of terminals of the aromatic polyamide is functional groups that can react with an epoxy group. The —COOH terminal and/or —NH₂ terminal of polyamide can be used as a functional group that can react with an epoxy group.

In one or plurality of embodiments of this disclosure, at least one of terminals of the aromatic polyamide is end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, the aromatic polyamide comprising:

an aromatic polyamide having repeat units of general formulas (I) and (II):

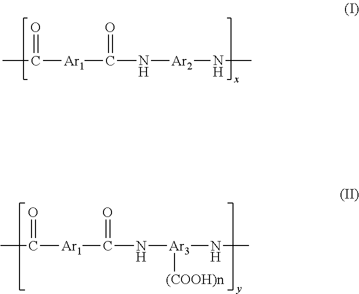

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

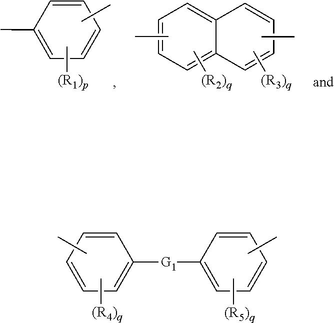

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R5 can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

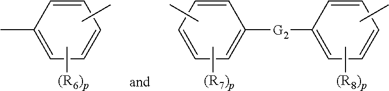

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group comprising:

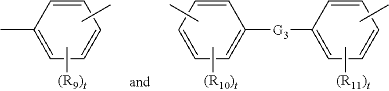

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

In one or plurality of embodiments of this disclosure, (I) and (II) are selected so that the polyamide is soluble in a polar solvent or a mixed solvent comprising one or more polar solvents. In one or plurality of embodiments of this disclosure, x varies from 90 to 100 mole % of the repeat structure (I), and y varies from 10 to 0 mole % of the repeat structure (II). In one or plurality of embodiments of this disclosure, the aromatic polyamide contains multiple repeat units with the structures (I) and (II) where Ar₁, Ar₂, and Ar₃ are the same or different.

In one or plurality of embodiments of this disclosure, the multifunctional epoxide is an epoxide having two or more glycidyl epoxy groups, or an epoxide having two or more alicyclic groups. In one or plurality of embodiments of this disclosure, the multifunctional epoxide selected from the group with general structures (III) and (IV):

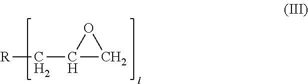

wherein l represents the number of glycidyl group, and R is selected from the group comprising:

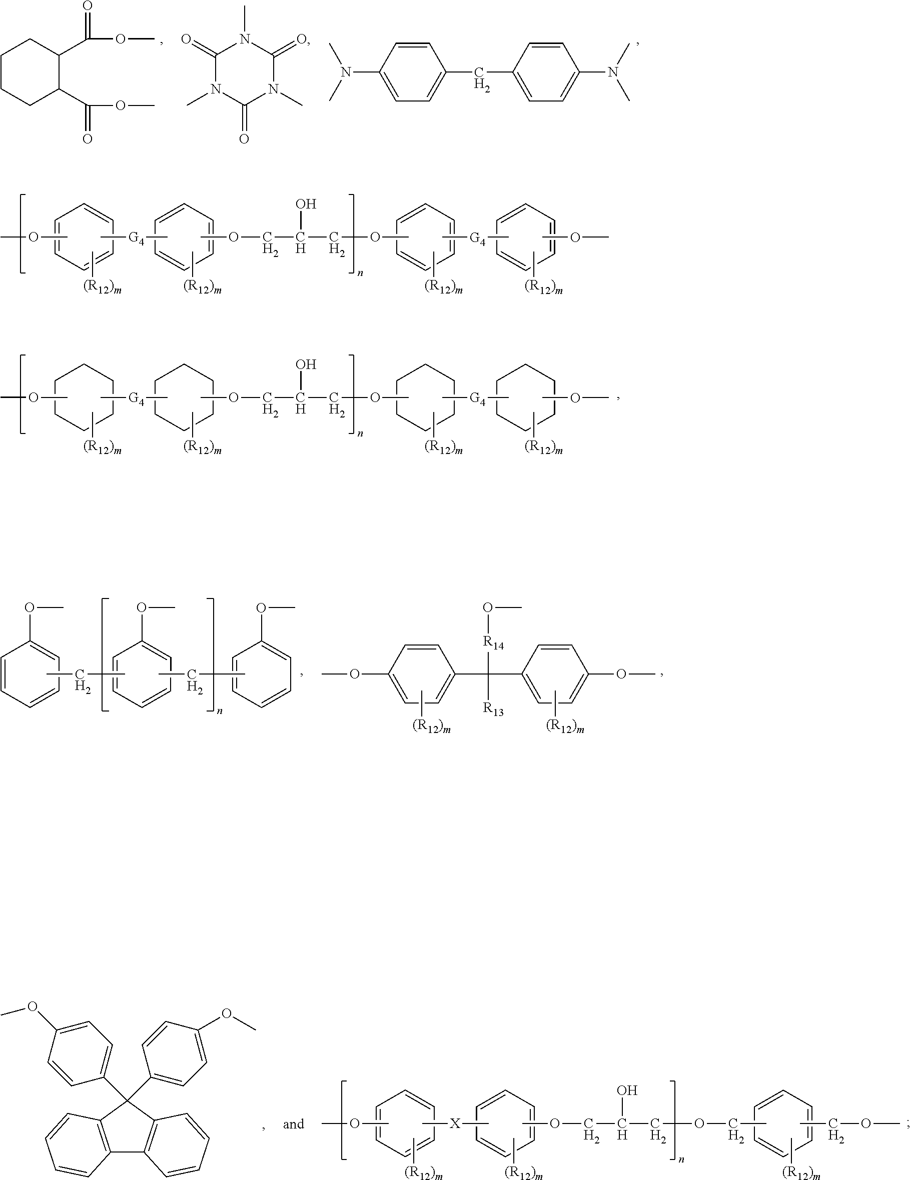

wherein m=1 to 4, and n and s are the average number of units and independently range from of 0 to 30;

wherein R₁₂s are same or different, and are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. G₄ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene, R₁₃ is a hydrogen or methyl group, and R₁₄ is a divalent organic group;

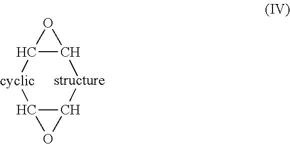

wherein the cyclic structure is selected from the group comprising:

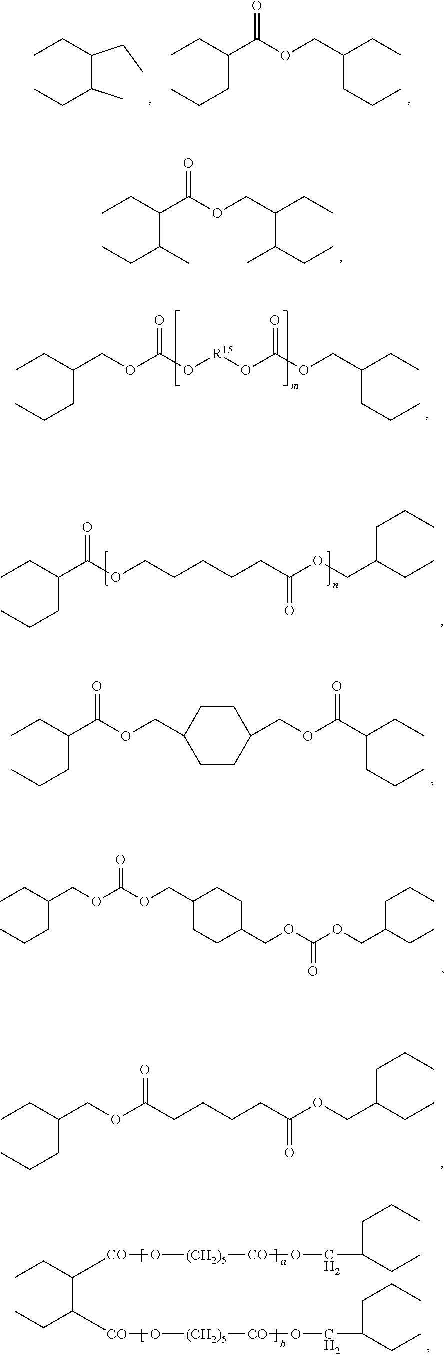

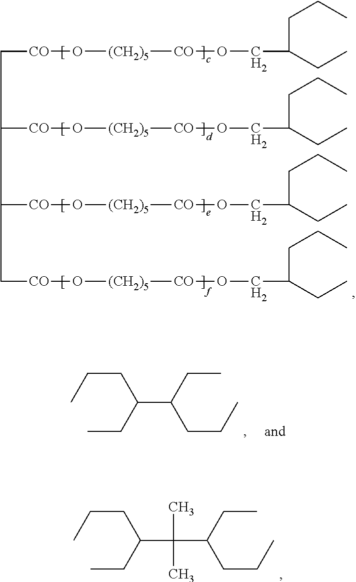

wherein R₁₅ is an alkyl chain having a carbon number of 2 to 18, the alkyl chain may be a straight chain, a branched chain, or a chain having cyclic skeleton, and wherein m and n are independently integer number of 1 to 30, and a, b, c, d, e and f are independently integer number of 0 to 30.

In one or plurality of embodiments of this disclosure, the multifunctional epoxide is

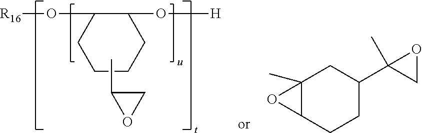

wherein R₁₆ is an alkyl chain having a carbon number of 2 to 18, the alkyl chain may be a straight chain, a branched chain, or a chain having cyclic skeleton, and wherein t and u are independently integer number of 1 to 30.

In one or plurality of embodiments of this disclosure, in terms of enhancement of solubility of the polyamide to the solvent, the solvent is a polar solvent or a mixed solvent comprising one or more polar solvents. In one or plurality of embodiments of this disclosure, in terms of enhancement of solubility of the polyamide to the solvent, the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.

In one or plurality of embodiments of this disclosure, the aromatic polyamide is obtained or obtainable by a process comprising the steps of:

a) dissolving one or more aromatic diamines in a solvent, where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.

In one or plurality of embodiments of this disclosure, one of the aromatic diamine selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.

In one or plurality of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, the solvent is a polar solvent or a mixed solvent comprising one or more polar solvents. In one or plurality of embodiments of this disclosure, the solvent is an organic and/or an inorganic solvent. In one or plurality of embodiments of this disclosure, in terms of enhancement of solubility of the polyamide to the solvent the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof, or a mixed solvent comprising at least one of polar solvent thereof.

In one or plurality of embodiments of this disclosure, the functional groups that can react with an epoxy group is greater than approximately one mol % to and less than approximately 10 mol % of the total diamine mixture. In one or plurality of embodiments of this disclosure, the functional group of the aromatic diamine containing a functional group that can react with an epoxy group is a carboxyl group. In one or plurality of embodiments of this disclosure, one of the diamines is 4,4′-diaminodiphenic acid or 3,5-diaminobenzoic acid. In one or plurality of embodiments of this disclosure, the functional group of the aromatic diamine containing a functional group that can react with an epoxy group is a hydroxyl group.

In one or plurality of embodiments of this disclosure, the reaction of hydrochloric acid with the acid trapping reagent yields a volatile product.

In one or plurality of embodiments of this disclosure, the acid trapping reagent is propylene oxide. In one or plurality of embodiments of this disclosure, the acid trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, the process to obtain the aromatic polyamide further comprises a step of end-capping of one or both of terminal —COOH group and terminal —NH₂ group of the polyamide, and/or a step of modifying one or both of terminal —COOH group and terminal —NH₂ group of the polyamide to one or more functional groups that can react with an epoxy group. The end-capping of the terminal is preferable from the point of enhancement of heat resistance property of the polyamide film The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, the multifunctional epoxide is selected from the group of phenolic epoxides and cyclic aliphatic epoxides. In one or plurality of embodiments of this disclosure, the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate. In one or plurality of embodiments of this disclosure, the amount of multifunctional epoxide is approximately 2 to 10% of the weight of the polyamide.

In one or plurality of embodiments of this disclosure, the polyamide is first isolated from the polyamide solution by precipitation and redissolved in a solvent prior to the addition of the multifunctional epoxide.

In one or plurality of embodiments of this disclosure, the solution is produced in the absence of inorganic salt.

In one or plurality of embodiments of this disclosure, the solution of the present disclosure is for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film.

Viewed from another aspect, this disclosure relates to a combination of the solution of the present disclosure and a multifunctional epoxide, wherein the solution of polyamide and the epoxide are separately packaged. In one or plurality of embodiments of this disclosure, the combination is a kit for use in the process for manufacturing a display element, an optical element or an illumination element disclosed in this disclosure.

Viewed from one aspect, this disclosure relates to a process for manufacturing a solution of an aromatic polyamide comprising the steps of:

a) dissolving one or more aromatic diamines in a solvent, where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.

In one or plurality of embodiments of this disclosure, one of the aromatic diamines is selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.

In one or plurality of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, between polyamide film and the base, the solvent is a polar solvent or a mixed solvent comprising one or more polar solvents. In one or plurality of embodiments of this disclosure, the solvent is an organic and/or an inorganic solvent. In one or plurality of embodiments of this disclosure, in terms of enhancement of solubility of the polyamide to the solvent, the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.

In one or plurality of embodiments of this disclosure, the functional groups that can react with an epoxy group is greater than approximately one mol % to and less than approximately 10 mol % of the total diamine mixture. In one or plurality of embodiments of this disclosure, the functional group of the aromatic diamine containing a functional group that can react with an epoxy group is a carboxyl group. In one or plurality of embodiments of this disclosure, one of the diamines is 4,4′-diaminodiphenic acid or 3,5-diaminobenzoic acid. In one or plurality of embodiments of this disclosure, the functional group of the aromatic diamine containing a functional group that can react with an epoxy group is a hydroxyl group.

In one or plurality of embodiments of this disclosure, the reaction of hydrochloric acid with the acid trapping reagent yields a volatile product.

In one or plurality of embodiments of this disclosure, the acid trapping reagent is propylene oxide. In one or plurality of embodiments of this disclosure, the acid trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, the process for manufacturing a solution of an aromatic polyamide further comprises a step of end-capping of one or both of terminal —COOH group and terminal —NH₂ group of the polyamide, and/or a step of modifying one or both of terminal —COOH group and terminal —NH₂ group of the polyamide to one or more functional groups that can react with an epoxy group. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, the multifunctional epoxide is selected from the group of phenolic epoxides and cyclic aliphatic epoxides. In one or plurality of embodiments of this disclosure, the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate. In one or plurality of embodiments of this disclosure, the amount of multifunctional epoxide is approximately 2 to 10% of the weight of the polyamide.

In one or plurality of embodiments of this disclosure, the polyamide is first isolated from the polyamide solution by precipitation and redissolved in a solvent prior to the addition of the multifunctional epoxide.

In one or plurality of embodiments of this disclosure, the solution is produced in the absence of inorganic salt.

In one or plurality of embodiments of this disclosure, the process for manufacturing a solution of an aromatic polyamide is for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film.

Viewed from one aspect, this disclosure relates to a process for manufacturing a display element, an optical element or an illumination element (hereinafter, referred also to as “the process of the present disclosure”), comprising the steps of:

a) dissolving one or more aromatic diamines in a solvent, where at least one of the diamines contains one or more functional groups that can react with an epoxy group;

b) reacting the at least one aromatic diamine mixture with at least one aromatic diacid dichloride, wherein hydrochloric acid and a polyamide solution are generated;

c) removing the free hydrochloric acid by reaction with a acid trapping reagent;

d) adding a multifunctional epoxide;

e) casting the resulting polyamide solution into a film onto a base at a temperature below approximately 200° C.;

f) heating the polyamide film on the base at a temperature that results is the film becoming solvent resistant; and

g) forming the display element, the optical element or the illumination element on the surface of the polyamide film.

In one or plurality of embodiments of this disclosure, one of the aromatic diamine selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.

In one or plurality of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, between polyamide film and the base, the solvent is a polar solvent or a mixed solvent comprising one or more polar solvents. In one or plurality of embodiments of this disclosure, the solvent is an organic and/or an inorganic solvent. In one or plurality of embodiments of this disclosure, in terms of enhancement of solubility of the polyamide to the solvent, the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.

In one or plurality of embodiments of this disclosure, the functional groups that can react with an epoxy group is greater than approximately one mol % to and less than approximately 10 mol % of the total diamine mixture. In one or plurality of embodiments of this disclosure, the functional group of the aromatic diamine containing a functional group that can react with an epoxy group is a carboxyl group. In one or plurality of embodiments of this disclosure, one of the diamines is 4,4′-diaminodiphenic acid or 3,5-diaminobenzoic acid. In one or plurality of embodiments of this disclosure, the functional group of the aromatic diamine containing a functional group that can react with an epoxy group is a hydroxyl group.

In one or plurality of embodiments of this disclosure, the reaction of hydrochloric acid with the acid trapping reagent yields a volatile product.

In one or plurality of embodiments of this disclosure, the acid trapping reagent is propylene oxide. In one or plurality of embodiments of this disclosure, the acid trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, the process for manufacturing a solution of an aromatic polyamide further comprises a step of end-capping of one or both of terminal —COOH group and terminal —NH₂ group of the polyamide, and/or a step of modifying one or both of terminal —COOH group and terminal —NH₂ group of the polyamide to one or more functional groups that can react with an epoxy group. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, the multifunctional epoxide is selected from the group of phenolic epoxides and cyclic aliphatic epoxides. In one or plurality of embodiments of this disclosure, the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate. In one or plurality of embodiments of this disclosure, the amount of multifunctional epoxide is approximately 2 to 10% of the weight of the polyamide.

In one or plurality of embodiments of this disclosure, the heating in the step f) is carried out under reduced pressure or an inert atmosphere, the temperature is less than 300° C., and the heating time is more than approximately 1 minute. In one or plurality of embodiments of this disclosure, the temperature is between approximately 200° C. and approximately 250° C. In one or plurality of embodiments of this disclosure, the heating time is more than approximately 1 minute and less than approximately 30 minutes.

In one or plurality of embodiments of this disclosure, the polyamide is first isolated from the polyamide solution by precipitation and redissolved in a solvent prior to the addition of the multifunctional epoxide.

In one or plurality of embodiments of this disclosure, the solution is produced in the absence of inorganic salt.

In one or plurality of embodiments of this disclosure, the process of the present disclosure, further comprising the step of:

h) de-bonding, from the base, the display element, the optical element or the illumination element formed on the base.

Viewed from one aspect, this disclosure relates to a process for manufacturing a display element, an optical element or an illumination element (hereinafter, referred also to as “the 2^{nd} process of the present disclosure”), comprising the steps of:

a) casting a solution of an aromatic polyamide into a film onto a base at a temperature below approximately 200° C.;

b) heating the polyamide film on the base at a temperature that results is the film becoming solvent resistant; and

c) forming the display element, the optical element or the illumination element on the surface of polyamide film;

wherein the solution of an aromatic polyamide comprising an aromatic polyamide, a solvent, and a multifunctional epoxide,

wherein the aromatic polyamide comprises one or more functional groups that can react with an epoxy group.

In one or plurality of embodiments of this disclosure, the functional group that can react with an epoxy group is a carboxyl group or a hydroxyl group.

In one or plurality of embodiments of this disclosure, in terms of enhancement of heat resistance property of the polyamide film, at least one of terminals of the aromatic polyamide is end-capped.

In one or plurality of embodiments of this disclosure, the aromatic polyamide comprising:

an aromatic polyamide having repeat units of general formulas (I) and (II):

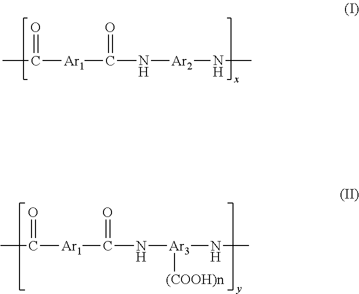

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

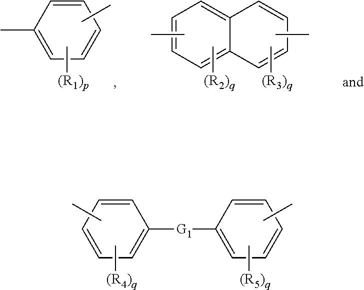

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

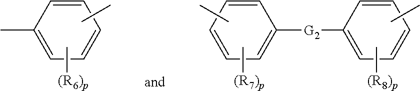

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group comprising:

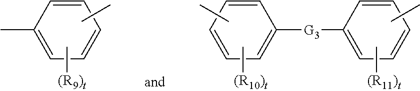

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

In one or plurality of embodiments of this disclosure, wherein (I) and (II) are selected so that the polyamide is soluble in a polar solvent or a mixed solvent comprising one or more polar solvents. In one or plurality of embodiments of this disclosure, x varies from 90 to 100 mole % of the repeat structure (I), and y varies from 10 to 0 mole % of the repeat structure (II). In one or plurality of embodiments of this disclosure, the aromatic polyamide contains multiple repeat units with the structures (I) and (II) where Ar₁, Ar₂, and Ar₃ are the same or different.

In one or plurality of embodiments of this disclosure, the multifunctional epoxide is an epoxide having two or more glycidyl epoxy groups, or an epoxide having two or more alicyclic groups. In one or plurality of embodiments of this disclosure, the multifunctional epoxide selected from the group with general structures (III) and (IV):

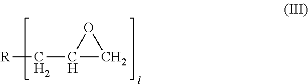

wherein l represents the number of glycidyl group, and R is selected from the group comprising:

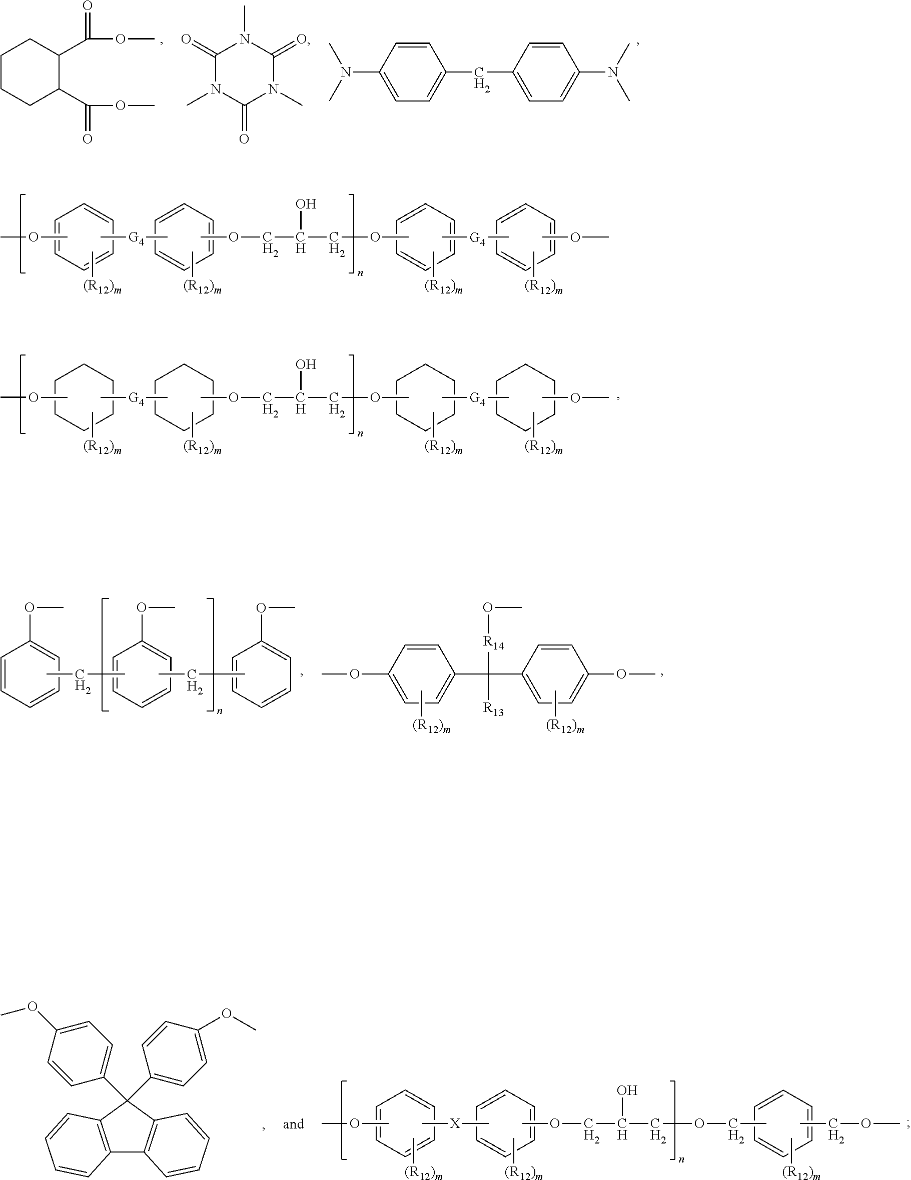

wherein m=1 to 4, and n and s are the average number of units and independently range from of 0 to 30;

wherein R₁₂s are same or different, and are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof G₄ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene, R₁₃ is a hydrogen or methyl group, and R₁₄ is a divalent organic group;

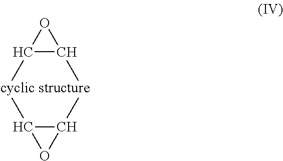

wherein the cyclic structure is selected from the group comprising:

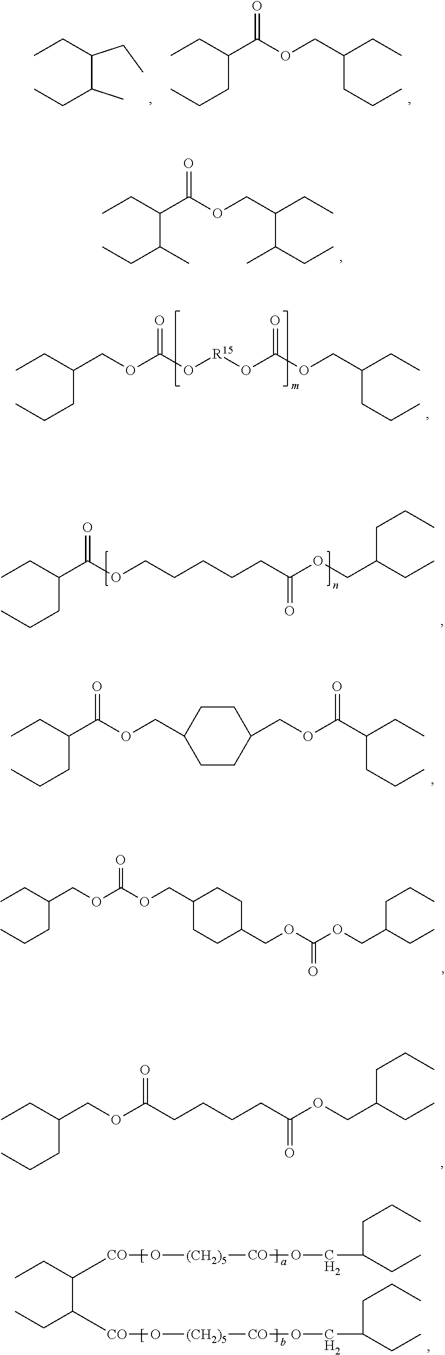

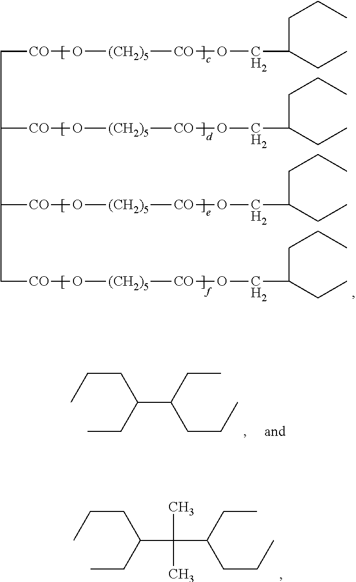

wherein R₁₅ is an alkyl chain having a carbon number of 2 to 18, the alkyl chain may be a straight chain, a branched chain, or a chain having cyclic skeleton, and wherein m and n are independently integer number of 1 to 30, and a, b, c, d, e and f are independently integer number of 0 to 30.

In one or plurality of embodiments of this disclosure, the multifunctional epoxide is

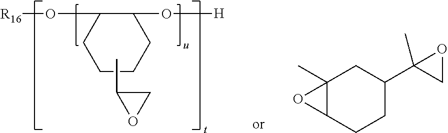

wherein R₁₆ is an alkyl chain having a carbon number of 2 to 18, the alkyl chain may be a straight chain, a branched chain, or a chain having cyclic skeleton, and wherein t and u are independently integer number of 1 to 30.

In one or plurality of embodiments of this disclosure, the multifunctional epoxide is selected from the group of phenolic epoxides and cyclic aliphatic epoxides. In one or plurality of embodiments of this disclosure, the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate. In one or plurality of embodiments of this disclosure, the amount of multifunctional epoxide is approximately 2 to 10% of the weight of the polyamide.

In one or plurality of embodiments of this disclosure, in terms of enhancement of solubility of the polyamide to the solvent, the solvent is a polar solvent or a mixed solvent comprising one or more polar solvents. In one or plurality of embodiments of this disclosure, in terms of enhancement of solubility of the polyamide to the solvent, the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.

In one or plurality of embodiments of this disclosure, the heating in the step f) is carried out under reduced pressure or an inert atmosphere, the temperature is less than 300° C., and the heating time is more than approximately 1 minute. In one or plurality of embodiments of this disclosure, the temperature is between approximately 200° C. and approximately 250° C. In one or plurality of embodiments of this disclosure, the heating time is more than approximately 1 minute and less than approximately 30 minutes.

In one or plurality of embodiments of this disclosure, the polyamide is first isolated from the polyamide solution by precipitation and redissolved in a solvent prior to the addition of the multifunctional epoxide.

In one or plurality of embodiments of this disclosure, in terms of enhancement of solubility of the polyamide to the solvent, the film is produced in the absence of inorganic salt

In one or plurality of embodiments of this disclosure, the 2^{nd} process of the present disclosure further comprising the step of:

h) de-bonding, from the base, the display element, the optical element or the illumination element formed on the base.

According to one embodiment of this disclosure, a process is provided for manufacturing a thermally and dimensionally stable transparent aromatic copolyamide film comprising the steps of: (A) dissolving one or more aromatic diamines in a polar solvent; (B) adding one or more aromatic diacid dichlorides, wherein hydrochloric acid and a polyamide solution is generated; (C) trapping the hydrochloric acid with a reagent; (D) adding approximately 5 weight % to approximately 10 weight % of a multifunctional compound containing epoxy groups; (E) casting the polyamide solution into a film by at a temperature less than approximately 200° C.; (F) curing the film at a temperature between approximately 200° C. and approximately 250° C. within less than 30 minutes under nitrogen or under reduced pressure. After the curing process, the film is resistant to most of the commonly used organic solvents, including NMP, DMAc, dimethyl sulfoxide (DMSO), etc

According to another embodiment of this disclosure, a transparent aromatic copolyamide film is produced having repeat units of a general formula (I) and (II):

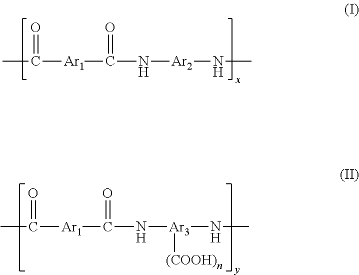

X represents the mole % of the repeat structure (I), which can vary from 90 to 100%, and Y represents the mole % on the repeat structure Y, which can vary from 10 to 0%. n is from 1 to 4.

Ar₁ is selected from the group of aromatic units which form aromatic diacid chlorides:

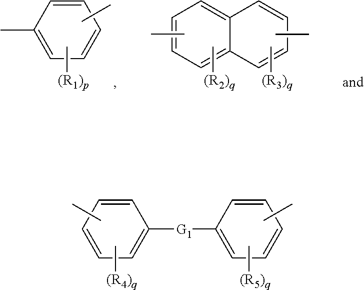

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R5 can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

Ar₂ is selected from the group of aromatic units which form diamines:

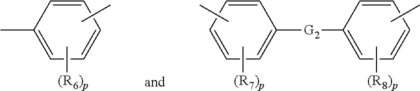

wherein p=4, wherein R₆, R₇, R₈ are selected from the group comprising hydrogen, halogen (fluoride, chloride, bromide, and iodide), alkyl, substituted alkyl such as halogenated alkyls, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

Ar₃ is selected from the group of aromatic units which form diamines containing free carboxylic acid group:

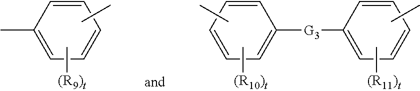

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (I) and (II) where Ar₁, Ar₂, and Ar₃ may be the same or different.

And one or more multifunctional organic compounds containing two or more epoxy groups (v)

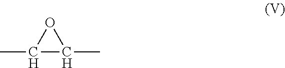

According to yet another embodiment of this disclosure a method of preparing a transparent film having a glass transition temperature greater than 300° C. and CTE less than 20 ppm/° C. is provided comprising the steps of:

(A) Reacting a mixture of aromatic diamines with a mixture of diacid dichlorides, in a polar solvent to afford a copolyamide and hydrochloric acid;

(B) Trapping the hydrochloric acid with a reagent such as propylene oxide (PrO);

(C) Adding a multifunctional compound containing epoxy groups;

(D) Directly casting the resulting polyamide solution into a film at a temperature below approximately 200° C.;

(E) Curing the polymer film at a temperature between approximately 200° C. and approximately 250° C.

This disclosure, as well as the polymer substrate films in the present disclosure, expand the utilization of AMOLEDs in portable devices by improving device electrical efficiency and the consumer experienced robustness of the display. In addition to the standard OLED display market, the substrate of the present disclosure will enable the development of the flexible display market. These displays can be used for conformable displays that can be integrated onto clothing, flexible e-paper and e-book displays, displays for smartcards, and a host of other new applications. For example, the polymer substrate films in the present disclosure can be used for flexible sensors. The new devices produced from the polymer substrate films in the present disclosure can dramatically impact daily life, by decreasing the cost and increasing accessibility and portability of information.

The polymers in the present disclosure can be prepared in a common organic solvent at room temperature (approximately 15° C. to about 25° C.). These polymers are produced in the absence of an inorganic salt. The resulting colorless and homogenous polymer solution can be used directly for subsequent film casting. No special polymerization reactor and no polymer isolation procedure is required. However, after the polymers are heated at a temperature between approximately 200° C. and approximately 250° C. for several minutes, the polymer films are insoluble and chemically resistant to swelling when exposed to inorganic or organic solvents. Thus, the process should be amenable to scale-up to metric ton quantities.

The polymers of the present disclosure are soluble in polar aprotic solvents without the need for the presence of inorganic salts. After the addition of a small amount of a multifunctional compound containing epoxy groups, they can be continuously solution cast directly from their polymerization mixtures using a roll-to-roll process to yield transparent, free standing films with thickness greater than approximately 10 μm. The films display high Tgs (>300° C.), low CTEs (<10 ppm/° C.), high transparencies (T >80% between 400 to 750 mn), excellent mechanical properties (tensile strengths >200 MPa), and low moisture absorptions (<2% @100% humidity at room temperature). Furthermore, the films show excellent solvent resistance after they are heated from approximately 200° C. to approximately 250° C. for less than 30 minutes. The films can also be made in a similar manner using a batch process.

The copolymer solutions can also be solution cast on supporting substrates such as thin glass, silica, and microelectronic devices. Curing is carried out by the process described above, but in this case the polymer is not isolated as a free standing film. The supported film thickness is greater than 5 μm.

The copolyamides can be prepared by polymerizing one or more aromatic diacid dichlorides as shown in the following general structures:

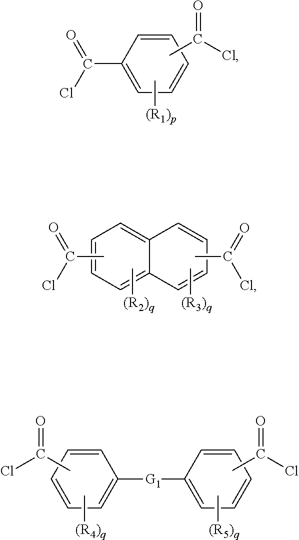

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

In one or more embodiments, one or more aromatic diamines are as shown in the following general structures:

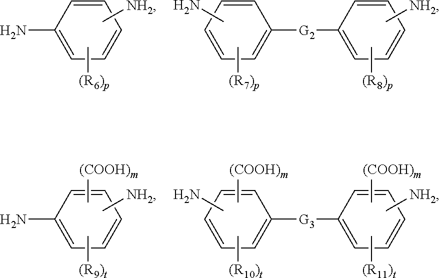

wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

Representative and illustrative examples of the useful aromatic diacid dichlorides in the disclosure are:

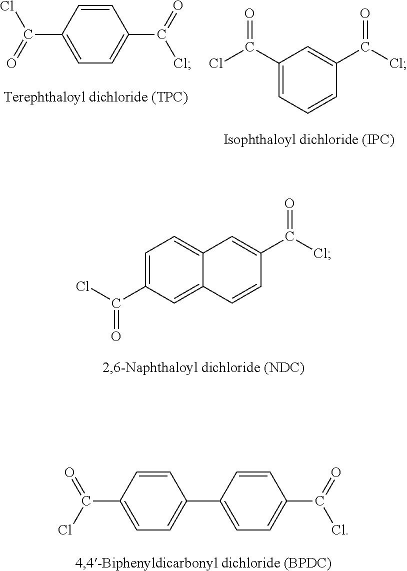

Representative and illustrative examples of the useful aromatic diamines in the disclosure are:

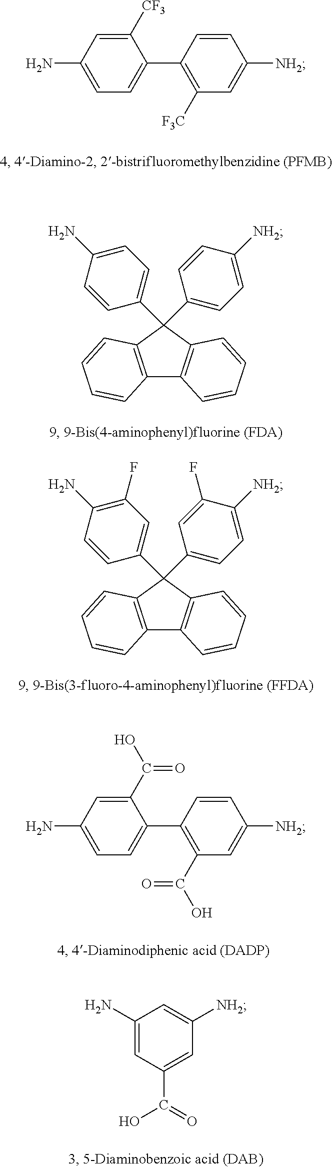 [SMILES: Nc1ccc(-c2ccc(N)cc2C(F)(F)F)c(C(F)(F)F)c1 ; Nc1ccc(C2(c3ccc(N)cc3)c3ccccc3-c3ccccc32)cc1 ; Nc1ccc(C2(c3ccc(N)c(F)c3)c3ccccc3-c3ccccc32)cc1F ; Nc1ccc(-c2ccc(N)cc2C(=O)O)c(C(=O)O)c1 ; Nc1cc(N)cc(C(=O)O)c1]

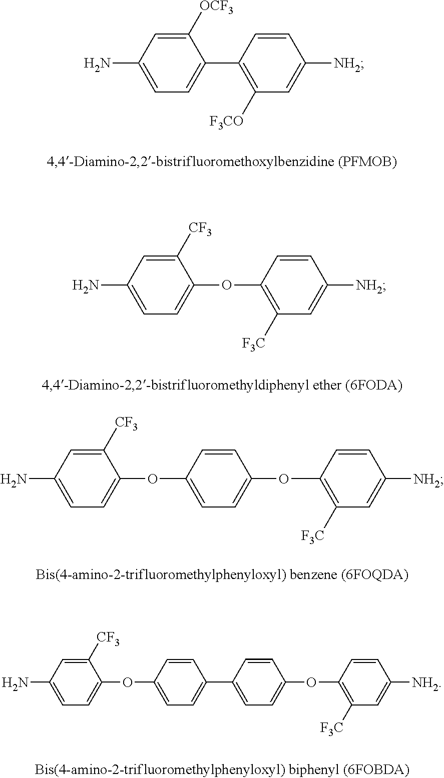 [SMILES: Nc1ccc(-c2ccc(N)cc2OC(F)(F)F)c(OC(F)(F)F)c1 ; Nc1ccc(Oc2ccc(N)cc2C(F)(F)F)c(C(F)(F)F)c1 ; Nc1ccc(Oc2ccc(Oc3ccc(N)cc3C(F)(F)F)cc2)c(C(F)(F)F)c1 ; Nc1ccc(Oc2ccc(-c3ccc(Oc4ccc(N)cc4C(F)(F)F)cc3)cc2)c(C(F)(F)F)c1]

Representative and illustrative examples of the useful aromatic diamines with pendant free carboxylic acid groups in the disclosure are:

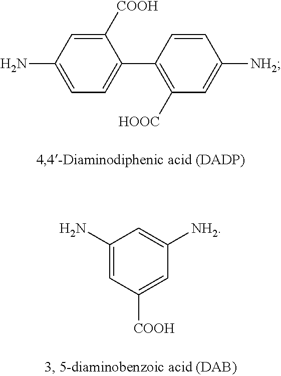 [SMILES: Nc1ccc(-c2ccc(N)cc2C(=O)O)c(C(=O)O)c1 ; Nc1cc(N)cc(C(=O)O)c1]

Representative and illustrative examples of multifunctional compounds containing epoxy groups useful in the disclosure are:

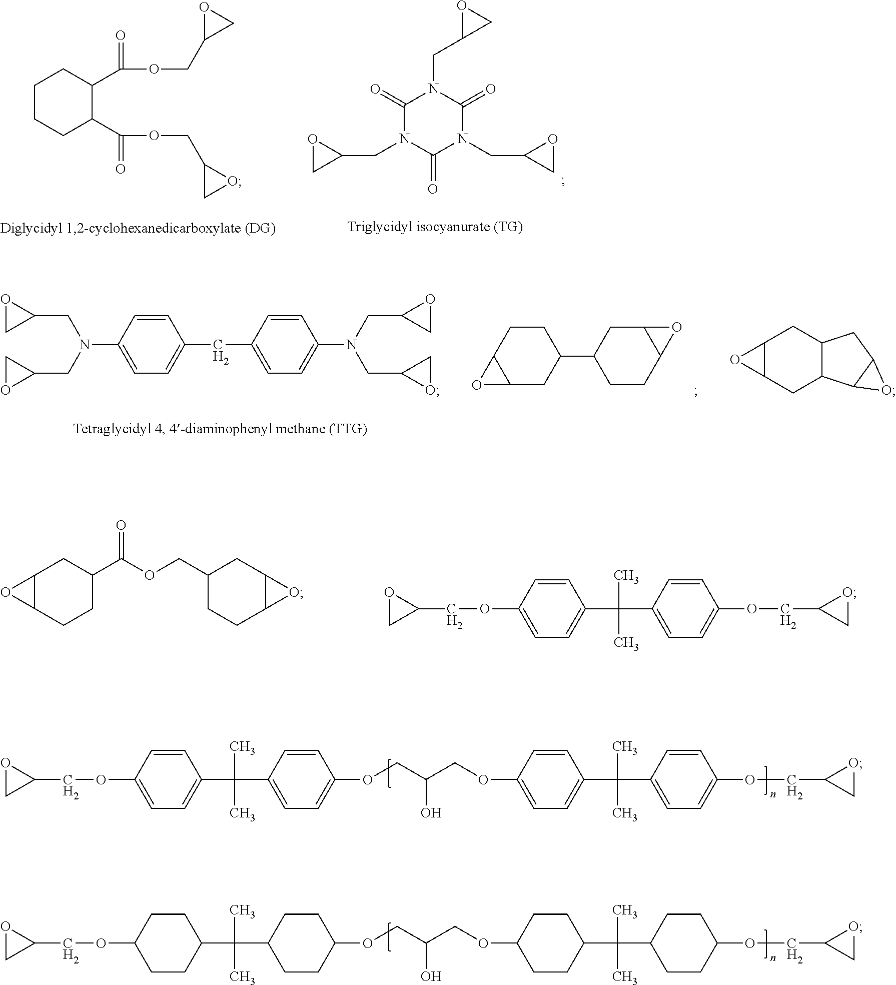

[Display Element, Optical Element, or Illumination Element]

The term “a display element, an optical element, or an illumination element” as used herein refers to an element that constitutes a display (display device), an optical device, or an illumination device, and examples of such elements include an organic EL element, a liquid crystal element, and organic EL illumination. Further, the term also covers a component of such elements, such as a thin film transistor (TFT) element, a color filter element or the like. In one or more embodiments, the display element, the optical element or the illumination element according to the present disclosure may include the polyamide film according to the present disclosure, may be produced using the solution of polyamide according to the present disclosure, or may use the polyamide film according to the present disclosure as the substrate of the display element, the optical element or the illumination element.

A display element, an optical element, or an illumination element such as an organic electro-luminescence (OEL) or organic light-emitting diode (OLED) is often produced by the process described in FIG. 2. Briefly, a polymer solution (varnish) is applied or casted onto a glass base or a silicon wafer base (step A), the applied polymer solution is cured to form a film (step B), an element such as OLED is formed on the film (step C), and then, the element such as OLED (product) is de-bonded from the base (step D). The solution of polyamide according to this disclosure can be the varnish of the step A.

<Non-Limiting Embodiment of Organic EL Element>

Hereinafter, one embodiment of an organic EL element as one embodiment of the display element according to the present disclosure will be described with reference to the drawing.

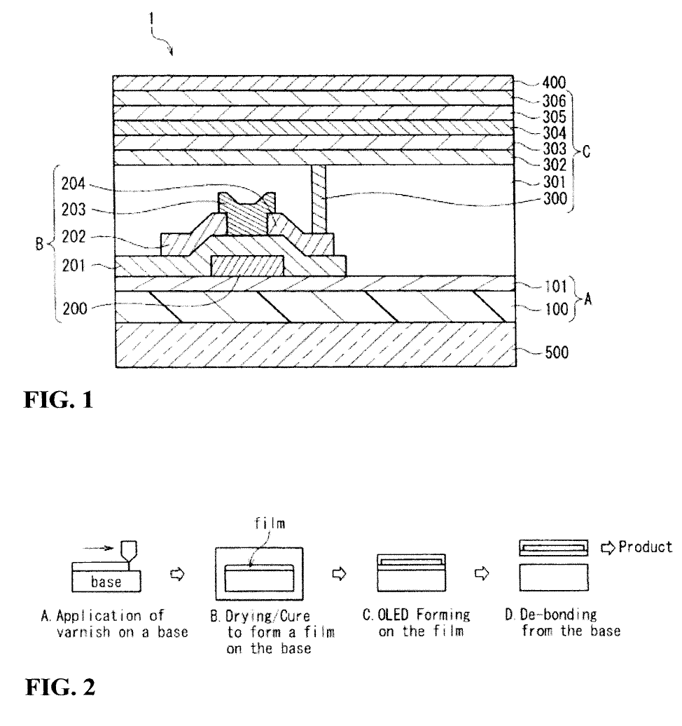

FIG. 1 is a schematic cross-sectional view showing an organic EL element 1 according to one embodiment. The organic EL element 1 includes a thin film transistor B formed on a substrate A and an organic EL layer C. Note that the organic EL element 1 is entirely covered with a sealing member 400. The organic EL element 1 may be separate from a base 500 or may include the base 500. Hereinafter, each component will be described in detail.

1. Substrate A

The substrate A includes a transparent resin substrate 100 and a gas barrier layer 101 formed on top of the transparent resin substrate 100. Here, the transparent resin substrate 100 is the polyamide film according to the present disclosure.

The transparent resin substrate 100 may have been annealed by heat. Annealing is effective in, for example, removing distortions and in improving the size stability against environmental changes.

The gas barrier layer 101 is a thin film made of SiOx, SiNx or the like, and is formed by a vacuum deposition method such as sputtering, CVD, vacuum deposition or the like. Generally, the gas barrier layer 101 has a thickness of, but is not limited to, about 10 nm to 100 nm. Here, the gas barrier layer 101 may be formed on the side of the transparent resin substrate 100 facing the gas barrier layer 101 in FIG. 1 or may be formed on the both sides of the transparent resin substrate 100.

2. Thin Film Transistor

The thin film transistor B includes a gate electrode 200, a gate insulating layer 201, a source electrode 202, an active layer 203, and a drain electrode 204. The thin film transistor B is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. For example, sputtering, vapor deposition, ion platting or the like may be use to form these transparent thin films Generally, these electrodes have a film thickness of; but is not limited to, about 50 nm to 200 nm.

The gate insulating film 201 is a transparent insulating thin film made of SiO₂, Al₂O₃ or the like, and is formed by sputtering, CVD, vacuum deposition, ion plating or the like. Generally, the gate insulating film 201 has a film thickness of; but is not limited to, about 10 nm to 1 μm.

The active layer 203 is a layer of; for example, single crystal silicon, low temperature polysilicon, amorphous silicon, or oxide semiconductor, and a material best suited to the active layer 203 is used as appropriate. The active layer is formed by sputtering or the like.

3. Organic EL Layer

The organic EL layer C includes a conductive connector 300, an insulative flattened layer 301, a lower electrode 302 as the anode of the organic EL element A, a hole transport layer 303, a light-emitting layer 304, an electron transport layer 305, and an upper electrode 306 as the cathode of the organic EL element A. The organic EL layer C is formed at least on the gas barrier layer 101 or on the thin film transistor B, and the lower electrode 302 and the drain electrode 204 of the thin film transistor B are connected to each other electrically through the connector 300. Instead, the lower electrode 302 of the thin film transistor B and the source electrode 202 may be connected to each other through the connector 300.

The lower electrode 302 is the anode of the organic EL element 1a, and is a transparent thin film made of indium tin oxide (ITO), indium zinc oxide (IZO), zinc oxide (ZnO) or the like. ITO is preferred because, for example, high transparency, and high conductivity can be achieved.

For the hole transport layer 303, the light-emitting layer 304, and the electron transport layer 305, conventionally-known materials for organic EL elements can be used as is.

The upper electrode 305 is a film composed of a layer of lithium fluoride (LiF) having a film thickness of 5 nm to 20 nm and a layer of aluminum (Al) having a film thickness of 50 nm to 200 nm. For example, vapor deposition may be use to form the film.

When producing a bottom emission type organic EL element, the upper electrode 306 of the organic EL element 1a may be configured to have optical reflectivity. Thereby, the upper electrode 306 can reflect in the display side direction light generated by the organic EL element A and traveled toward the upper side as the opposite direction to the display side. Since the reflected light is also utilized for a display purpose, the emission efficiency of the organic EL element can be improved.

[Method of Producing Display Element, Optical Element, or Illumination Element]

Another aspect of the present disclosure relates to a method of producing a display element, an optical element, or an illumination element. In one or more embodiments, the production method according to the present disclosure is a method of producing the display element, the optical element, or the illumination element according to the present disclosure. Further, in one or more embodiments, the production method according to the present disclosure is a method of producing a display element, an optical element, or an illumination element, which includes the steps of: applying the polyamide resin composition according to the present disclosure onto a base; forming a polyamide film after the application step; and forming the display element, the optical element, or the illumination element on the side of the base not in contact with the polyamide resin film. The production method according to the present disclosure may further include the step of de-bonding, from the base, the display element, the optical element, or the illumination element formed on the base.

<Non-Limiting Embodiment of Method of Producing Organic EL Element>

As one embodiment of the method of producing a display element according to the present disclosure, hereinafter, one embodiment of a method of producing an organic EL element will be described with reference to the drawing.

A method of producing the organic EL element 1 shown in FIG. 1 includes a fixing step, a gas barrier layer preparation step, a thin film transistor preparation step, an organic EL layer preparation step, a sealing step and a de-bonding step. Hereinafter, each step will be described in detail.

1. Fixing Step

In the fixing step, the transparent resin substrate 100 is fixed onto the base 500. A way to fix the transparent resin substrate 100 to the base 500 is not particularly limited. For example, an adhesive may be applied between the base 500 and the transparent substrate or a part of the transparent resin substrate 100 may be fused and attached to the base 500 to fix the transparent resin substrate 100 to the base 500. Further, as the material of the base, glass, metal, silicon, resin or the like is used, for example. These materials may be used alone or in combination of two or more as appropriate. Furthermore, the transparent resin substrate 100 may be attached to the base 500 by applying a releasing agent or the like to the base 500 and placing the transparent resin substrate 100 on the applied releasing agent. In one or more embodiments, the polyamide film 100 is formed by applying the polyamide resin composition according to the present disclosure to the base 500, and drying the applied polyamide resin composition.

2. Gas Bather Layer Preparation Step

In the gas barrier layer preparation step, the gas barrier layer 101 is prepared on the transparent resin substrate 100. A way to prepare the gas barrier layer 101 is not particularly limited, and a known method can be used.

3. Thin Film Transistor Preparation Step

In the thin film transistor preparation step, the thin film transistor B is prepared on the gas bather layer. A way to prepare the thin film transistor B is not particularly limited, and a known method can be used.

4. Organic EL Layer Preparation Step

The organic EL layer preparation step includes a first step and a second step. In the first step, the flattened layer 301 is formed. The flattened layer 301 can be formed by, for example, spin-coating, slit-coating, or ink-jetting a photosensitive transparent resin. At that time, an opening needs to be formed in the flattened layer 301 so that the connector 300 can be formed in the second step. Generally, the flattened layer has a film thickness of, but is not limited to, about 100 nm to 2 μm.

In the second step, first, the connector 300 and the lower electrode 302 are formed at the same time. Sputtering, vapor deposition, ion platting or the like may be used to form the connector 300 and the lower electrode 302. Generally, these electrodes have a film thickness of, but is not limited to, about 50 nm to 200 nm. Subsequently, the hole transport layer 303, the light-emitting layer 304, the electron transport layer 305, and the upper electrode 306 as the cathode of the organic EL element A are formed. To form these components, a method such as vapor deposition, application, or the like can be used as appropriate in accordance with the materials to be used and the laminate structure. Further, irrespective of the explanations given in this example, other layers may be chosen from known organic layers such as a hole injection layer, an electron transport layer, a hole blocking layer and an electron blocking layer as needed and be used to configuring the organic layers of the organic EL element A.

5. Sealing Step

In the sealing step, the organic EL layer A is sealed with the sealing member 307 from top of the upper electrode 306. For example, a glass material, a resin material, a ceramics material, a metal material, a metal compound or a composite thereof can be used to form the sealing member 307, and a material best suited to the sealing member 307 can be chosen as appropriate.

6. De-Bonding Step

In the de-bonding step, the organic EL element 1 prepared is stripped from the base 500. To implement the de-bonding step, for example, the organic EL element 1 may be physically stripped from the base 500. At that time, the base 500 may be provided with a de-bonding layer, or a wire may be inserted between the base 500 and the display element to remove the organic EL element. Further, examples of other methods of de-bonding the organic EL element 1 from the base 500 include the following: forming a de-bonding layer on the base 500 except at ends, and cutting, after the preparation of the element, the inner part from the ends to remove the element from the base; providing a layer of silicon or the like between the base 500 and the element, and irradiating the silicon layer with a laser to strip the element; applying heat to the base 500 to separate the base 500 and the transparent substrate from each other; and removing the base 500 using a solvent. These methods may be used alone or any of these methods may be used in combination of two or more. Especially in one or more embodiments, the strength of adhesion between PA film and the Base can be controlled by silane coupling agent, so that the organic EL element 1 may be physically stripped without using the complicated process such as described above.

In one or more embodiments, the organic EL element obtained by the method of producing a display, optical or illumination element according to the present embodiment has excellent characteristics such as excellent transparency and heat-resistance, low linear expansivity and low optical anisotropy.

[Display Device, Optical Device, and Illumination Device]

Another aspect of the present disclosure relates to a display device, an optical device, or an illumination device using the display element, the optical element, or the illumination element according to the present disclosure, or a method of producing the display device, the optical device, or the illumination device. Examples of the display device include, but are not limited to, an imaging element, examples of the optical device include, but are not limited to, a photoelectric complex circuit, and examples of the illumination device include, but are not limited to, a TFT-LCD and OEL illumination.

This disclosure may relate to any of the following.
[a1] A solution of polyamide comprising:

an aromatic polyamide and a solvent;

wherein the aromatic polyamide comprises one or more functional groups that can react with an epoxy group.
[a2] The solution according to [a1], further comprising a multifunctional epoxide.
[a3] The solution according to [a1] or [a2], wherein at least one of terminals of the aromatic polyamide is functional groups that can react with an epoxy group.
[a4] The solution according to any one of [a1] to [a3], wherein at least one of terminals of the aromatic polyamide is end-capped.
[a5] The solution according to any one of [a1] to [a4], wherein the aromatic polyamide comprising:

an aromatic polyamide having repeat units of general formulas (I) and (II):

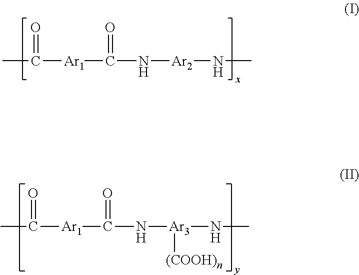

wherein x represents mole % of the repeat structure (I), y represents mole % of the repeat structure (II), x varies from 90 to 100, and y varies from 10 to 0;

wherein n=1 to 4;

wherein Ar₁ is selected from the group comprising:

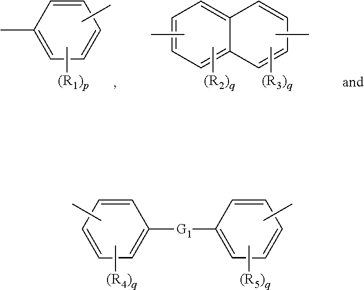

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

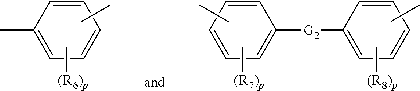

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof; wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group comprising:

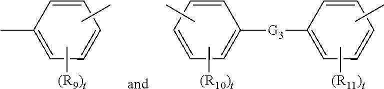

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.
[a6] The solution according to [a5], wherein (I) and (II) are selected so that the polyamide is soluble in a polar solvent or a mixed solvent comprising one or more polar solvents.
[a7] The solution according to [a5] or [a6], wherein x varies from 90 to 99 mole %, and y varies from 10 to 1 mole %.
[a8] The solution according to any one of [a5] to [a7], wherein the aromatic polyamide contains multiple repeat units with the structures (I) and (II) where Ar₁, Ar₂, and Ar₃ are the same or different.
[a9] The solution according to any one of [a2] to [a8], wherein the multifunctional epoxide is an epoxide having two or more glycidyl epoxy groups, or an epoxide having two or more alicyclic groups.
[a10] The solution according to any one of [a2] to [a9], wherein the multifunctional epoxide selected from the group with general structures (III) and (IV):

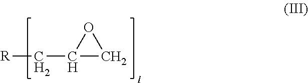

wherein l represents the number of glycidyl group, and R is selected from the group comprising:

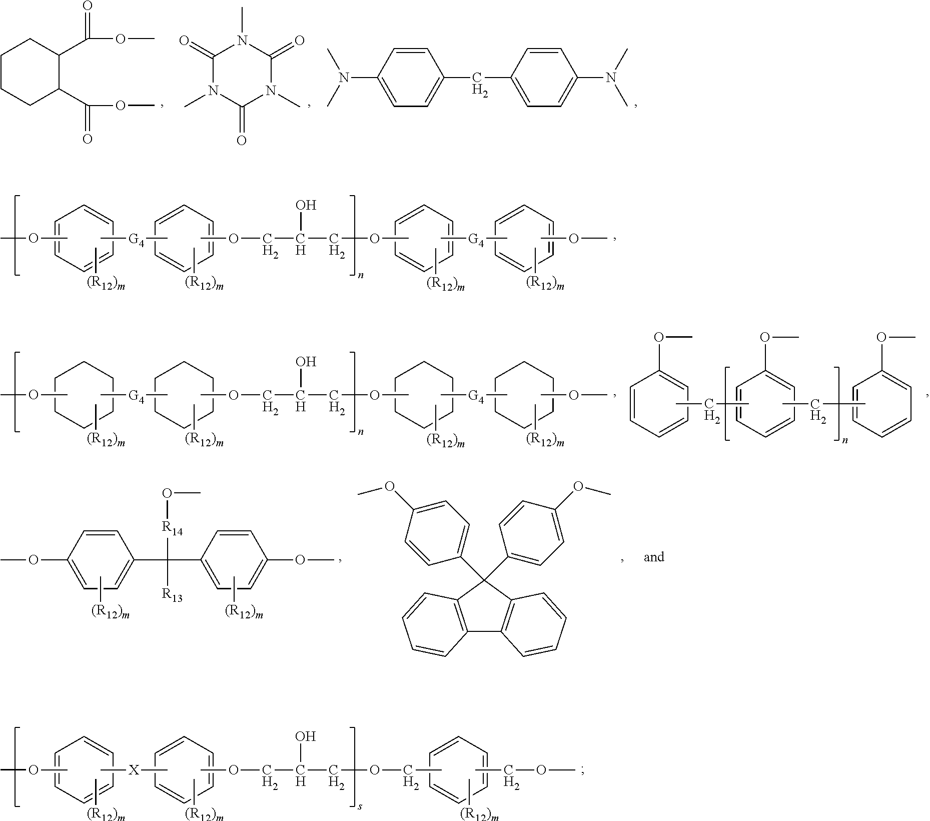

wherein m=1 to 4, and n and s are the average number of units and independently range from of 0 to 30;

wherein R₁₂s are same or different, and are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₄ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene, R₁₃ is a hydrogen or methyl group, and R₁₄ is a divalent organic group;

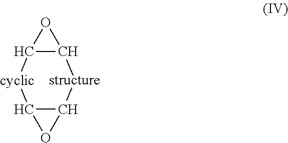

wherein the cyclic structure is selected from the group comprising:

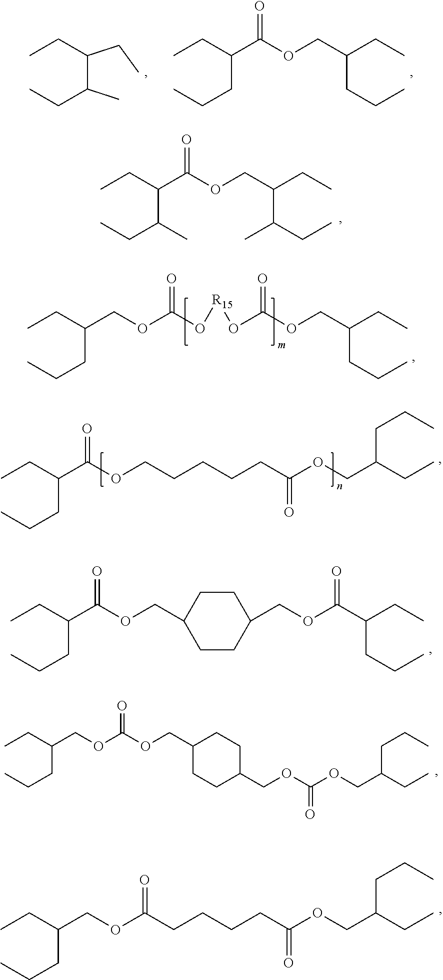

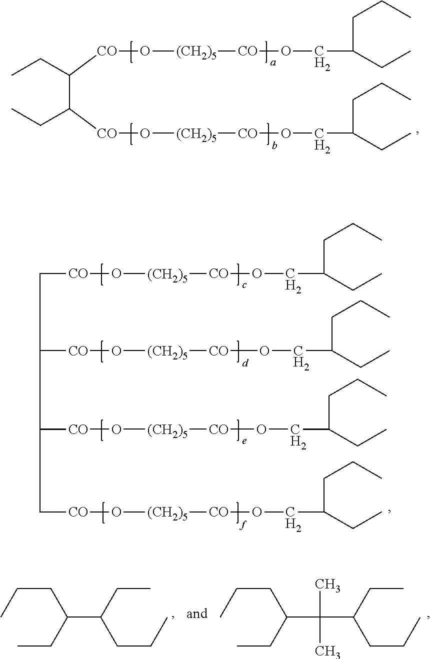

wherein R₁₅ is an alkyl chain having a carbon number of 2 to 18, the alkyl chain may be a straight chain, a branched chain, or a chain having cyclic skeleton, and wherein m and n are independently integer number of 1 to 30, and a, b, c, d, e and f are independently integer number of 0 to 30.
[a11] The solution according to any one of [a2] to [a10], wherein the multifunctional epoxide is

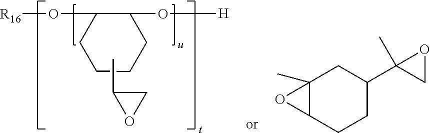

wherein R₁₆ is an alkyl chain having a carbon number of 2 to 18, the alkyl chain may be a straight chain, a branched chain, or a chain having cyclic skeleton, and wherein t and u are independently integer number of 1 to 30.
[a12] The solution according to any one of [a1] to [a11], wherein the solvent is a polar solvent or a mixed solvent comprising one or more polar solvents.
[a13] The solution according to any one of [a1] to [a12], wherein the solvent is an organic and/or an inorganic solvent.
[a14] The solution according to any one of [a1] to [a13], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[a15] The solution according to any one of [a1] to [a14], wherein the aromatic polyamide is obtained by a process comprising the steps of:

a) dissolving one or more aromatic diamines in a solvent,
where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.
[a16] The solution according to [a15], wherein one of the aromatic diamines is selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.
[a17] The solution according to [a15] or [a16], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[a18] The solution according to any one of [a15] to [a17] wherein the solvent is a polar solvent or a mixed solvent comprising one or more polar solvents.
[a19] The solution according to any one of [a15] to[a18], wherein the solvent is an organic and/or an inorganic solvent.
[a20] The solution according to any one of [a15] to [a19] wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[a21] The solution according to any one of [a15] to [a20], wherein the functional groups that can react with an epoxy group is greater than approximately one mol % to and less than approximately 10 mol % of the total diamine mixture.
[a22] The solution according to any one of [a15] to [a21], wherein the functional group of the aromatic diamine containing a functional group that can react with an epoxy group is a carboxyl group.
[a23] The solution according to any one of [a15] to [a22], wherein one of the diamines is 4,4′-diaminodiphenic acid or 3,5-diaminobenzoic acid.
[a24] The solution according to any one of [a15] to [a23], wherein the functional group of the aromatic diamine containing a functional group that can react with an epoxy group is a hydroxyl group.
[a25] The solution according to any one of [a15] to [a24], wherein the reaction of hydrochloric acid with the acid trapping reagent yields a volatile product.
[a26] The solution according to [a25], wherein the acid trapping reagent is propylene oxide.
[a27] The solution according to [a26], wherein the acid trapping reagent is an inorganic salt.
[a28] The solution according to any one of [a15] to [a27], wherein the reagent is added to the mixture before or during the reacting step (b).
[a29] The solution according to any one of [a15] to [a28], wherein the process further comprises a step of end-capping for one or both of terminal —COOH group and terminal —NH₂ group of the polyamide, and/or a step of modifying one or both of terminal —COOH group and terminal —NH₂ group of the polyamide to one or more functional groups that can react with an epoxy group.
[a30] The solution according to any one of [a2] to [a29], wherein the multifunctional epoxide is selected from the group of phenolic epoxides and cyclic aliphatic epoxides.
[a31] The solution according to any one of [a2] to [a30], wherein the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate.
[a32] The solution according to any one of [a2] to [a31], wherein the amount of multifunctional epoxide is approximately 2 to 10% of the weight of the polyamide.
[a33] The solution according to any one of [a15] to [a32], wherein the polyamide is first isolated from the polyamide solution by precipitation and redissolved in a solvent prior to the addition of the multifunctional epoxy compound.
[a34] The solution according to any one of [a15] to [a33], wherein the solution is produced in the absence of inorganic salt
[a35] The solution according to any one of [a1] to [a34] for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film.
[a36] A combination of the solution of polyamide according to any one of [a1] to [a35] and a multifunctional epoxide, wherein the solution of polyamide and the epoxide are separately packaged.
[b1] A process for manufacturing a solution of an aromatic polyamide comprising the steps of:

a) dissolving one or more aromatic diamines in a solvent,
where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) optionally, adding a multifunctional epoxide.
[b2] The process according to [b1], wherein one of the aromatic diamines is selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.
[b3] The process according to [b1] or [b2], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[b4] The process according to any one of [1] to [b3], wherein the solvent is a polar solvent or a mixed solvent comprising one or more polar solvents.
[b5] The process according to any one of [1] to [b4], wherein the solvent is an organic and/or an inorganic solvent.
[b6] The process according to any one of [1] to [b5], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[b7] The process according to any one of [1] to [b7], wherein the functional groups that can react with an epoxy group is greater than approximately one mol % to and less than approximately 10 mol % of the total diamine mixture.
[b8] The process according to any one of [1] to [b7], wherein the functional group of the aromatic diamine containing a functional group that can react with an epoxy group is a carboxyl group.
[b9] The process according to any one of [1] to [b8], wherein one of the diamines is 4,4′-diaminodiphenic acid or 3,5-diaminobenzoic acid.
[b10] The solution according to any one of [b1] to [b9], wherein the functional group of the aromatic diamine containing a functional group that can react with an epoxy group is a hydroxyl group.
[b11] The process according to any one of [b1] to [b10], wherein the reaction of hydrochloric acid with the acid trapping reagent yields a volatile product
[b12] The process according to [b11], wherein the acid trapping reagent is propylene oxide.
[b13] The process according to [b12], wherein the acid trapping reagent is an inorganic salt.
[b14] The process according to any one of [b1] to [b13], wherein the acid trapping reagent is added to the mixture before or during the reacting step (b).
[b15] The process according to any one of [b1] to [b15], wherein the process further comprises the step of end-capping for one or both of terminal —COOH group and terminal —NH₂ group of the polyamide, and/or a step of modifying one or both of terminal —COOH group and terminal —NH₂ group of the polyamide to one or more functional groups that can react with an epoxy group.
[b16] The solution according to any one of [b1] to [b15], wherein the multifunctional epoxide is selected from the group of phenolic epoxides and cyclic aliphatic epoxides.
[b17] The process according to any one of [b1] to [b16], wherein the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate.
[b18] The process according to any one of [b1] to [b17], wherein the amount of multifunctional epoxide is approximately 2 to 10% of the weight of the polyamide.
[b19] The process according to any one of [b1] to [b18], wherein the polyamide is first isolated from the polyamide solution by precipitation and redissolved in a polar solvent prior to the addition of the multifunctional epoxy compound.
[b20] The process according to any one of [b1] to [b19], wherein the solution is produced in the absence of inorganic salt.
[b21] The process according to any one of [b1] to [b20] for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film.
[c1] A process for manufacturing a display element, an optical element or an illumination element, comprising the steps of:

a) dissolving one or more aromatic diamines in a solvent,
where at least one of the diamines contains one or more functional groups that can react with an epoxy group;

b) reacting the diamine mixture with at least one aromatic diacid dichloride, wherein hydrochloric acid and a polyamide solution is generated;

c) removing the free hydrochloric acid by reaction with an acid trapping reagent;

d) adding a multifunctional epoxide;

e) casting the resulting polyamide solution into a film onto a base at a temperature below approximately 200° C.;

f) heating the polyamide film on the base at a temperature that results is the film becoming solvent resistant; and

g) forming the display element, the optical element or the illumination element on the surface of the polyamide film.
[c2] The process according to [c1], wherein one of the aromatic diamines selected from the group comprising 4,4′-diamino-2,2′-bistrifluoromethylbenzidine 9,9-bis(4aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.
[c3] The process according to [c1] or [c2], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[c4] The process according to any one of [c1] to[c3], wherein the solvent is a polar solvent or a mixed solvent comprising one or more polar solvents.
[c5] The process according to any one of [c1] to [c4], wherein the solvent is an organic and/or an inorganic solvent.
[c6] The process according to any one of [c1] to [c5], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[c7] The process according to any one of [c1] to [c6], wherein the functional groups that can react with an epoxy group is greater than approximately one mol % to and less than approximately 10 mol % of the total diamine mixture.
[c8] The process according to any one of [c1] to [c7], wherein the functional group of the aromatic diamine containing a functional group that can react with an epoxy group is a carboxyl group.
[c9] The process according to any one of [c1] to [c8], wherein one of the diamine is 4,4′-diaminodiphenic acid or 3,5-diaminobenzoic acid.
[c10] The solution according to any one of [c1] to [c9], wherein the functional group of the aromatic diamine containing a functional group that can react with an epoxy group is a hydroxyl group.
[c11] The process according to any one of [c1] to [c10], wherein the reaction of hydrochloric acid with the acid trapping reagent yields a volatile product and the film is cast directly from the reaction mixture.
[c12] The process according to [c11], wherein the acid trapping reagent is propylene oxide.
[c13] The process according to [c12], wherein the acid trapping reagent is an inorganic salt.
[c14] The process according to any one of [c1] to [c13], wherein the acid trapping reagent is added to the mixture before or during the reacting step (b).
[c15] The process according to any one of [c1] to [c14], wherein the process further comprises the step of end-capping for one or both of terminal —COOH group and terminal —NH₂ group of the polyamide, and/or a step of modifying one or both of terminal —COOH group and terminal —NH₂ group of the polyamide to one or more functional groups that can react with an epoxy group.
[c16] The solution according to any one of [c1] to [c15], wherein the multifunctional epoxide is selected from the group of phenolic epoxides and cyclic aliphatic epoxides.
[c17] The process according to any one of [c1]1 to [c16], wherein the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate.
[c18] The process according to any one of [c1] to [c17], wherein the amount of multifunctional epoxide is approximately 2 to 10% of the weight of the polyamide.
[c19] The process according to any one of [c1] to [c18], wherein the heating in the step f) is carried out under reduced pressure or an inert atmosphere, the temperature is less than 300° C., and the heating time is more than approximately 1 minute.
[c20] The process according to [c19], wherein the temperature is between approximately 200° C. and approximately 250° C.
[c21] The process according to [c19] or [c20], wherein the heating time is more than approximately 1 minute and less than approximately 30 minutes.
[c22] The process according to any one of [c1] to [c21], wherein the polyamide is first isolated from the polyamide solution by precipitation and redissolved in a solvent prior to the addition of the multifunctional epoxy compound.
[c23] The process according to any one of [c1] to [c22], wherein the film is produced in the absence of inorganic salt.
[c24] The process according to any one of [c1] to [c23], further comprising the step of:

h) de-bonding, from the base, the display element, the optical element or the illumination element formed on the base.
[d1] A process for manufacturing a display element, an optical element or an illumination element, comprising the steps of:

a) casting a solution of an aromatic polyamide into a film onto a base at a temperature below approximately 200° C.;

b) heating the polyamide film on the base at a temperature that results is the film becoming solvent resistant; and

c) forming the display element, the optical element or the illumination element on the surface of polyamide film;

wherein the solution of an aromatic polyamide comprising an aromatic polyamide, a solvent, and a multifunctional epoxide,

wherein the aromatic polyamide comprises one or more functional groups that can react with an epoxy group.
[d2] The process according to [d1], wherein the functional group that can react with an epoxy group is a carboxyl group or a hydroxyl group.
[d3] The process according to [d1] or [d2], wherein at least one of terminals of the aromatic polyamide are end-capped.
[d4] The process according to any one of [d1] to [d3], wherein the aromatic polyamide comprising:

an aromatic polyamide having repeat units of general formulas (I) and (II):

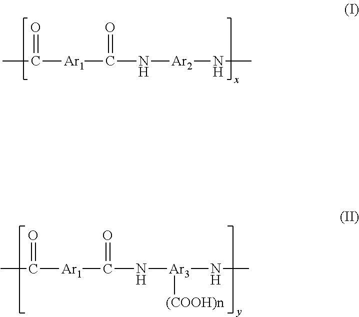

wherein x represents mole % of the repeat structure (I), y represents mole % of the repeat structure (II), x varies from 90 to 100, and y varies from 10 to 0;

wherein n=1 to 4;

wherein Ar₁ is selected from the group comprising:

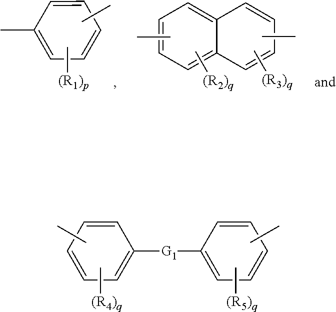

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

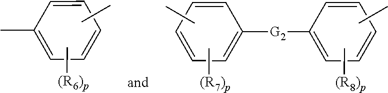

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof; wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group comprising:

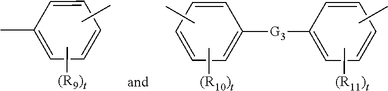

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.
[d5] The process according to [d4], wherein (I) and (II) are selected so that the polyamide is soluble in a polar solvent or a mixed solvent comprising one or more polar solvents.
[d6] The process according to [d4] or [d5], wherein x varies from 90 to 99 mole % and y varies 10 to 1 mole %.
[d7] The process according to any one of [d4] to [d6], wherein the aromatic polyamide contains multiple repeat units with the structures (I) and (II) where Ar₁, Ar₂, and Ar₃ are the same or different.
[d8] The process according to any one of [d1] to [d7], wherein the multifunctional epoxide is an epoxide having two or more glycidyl epoxy groups, or an epoxide having two or more alicyclic groups.
[d9] The process according to any one of [d1] to [d81], wherein the multifunctional epoxide selected from the group with general structures (III) and (IV):

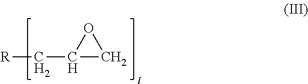

wherein l represents the number of glycidyl group, and R is selected from the group comprising:

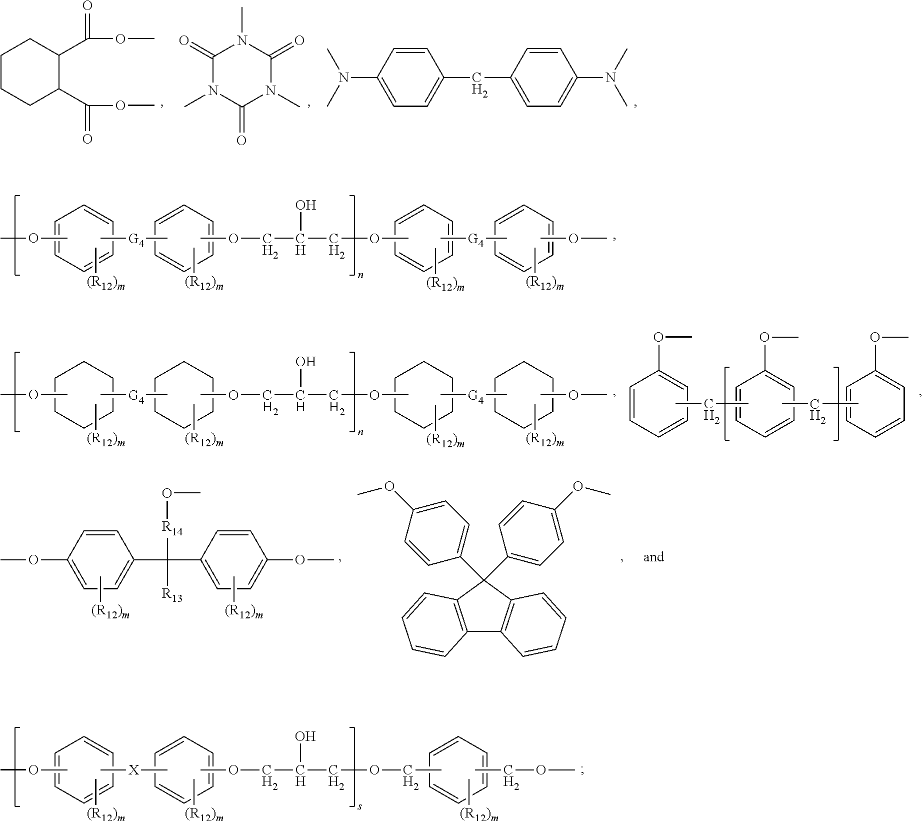

wherein m=1 to 4, and n and s are the average number of units and independently range from of 0 to 30;

wherein R₁₂s are same or different, and are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₄ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene, R₁₃ is a hydrogen or methyl group, and R₁₄ is a divalent organic group;

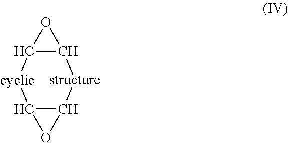

wherein the cyclic structure is selected from the group comprising:

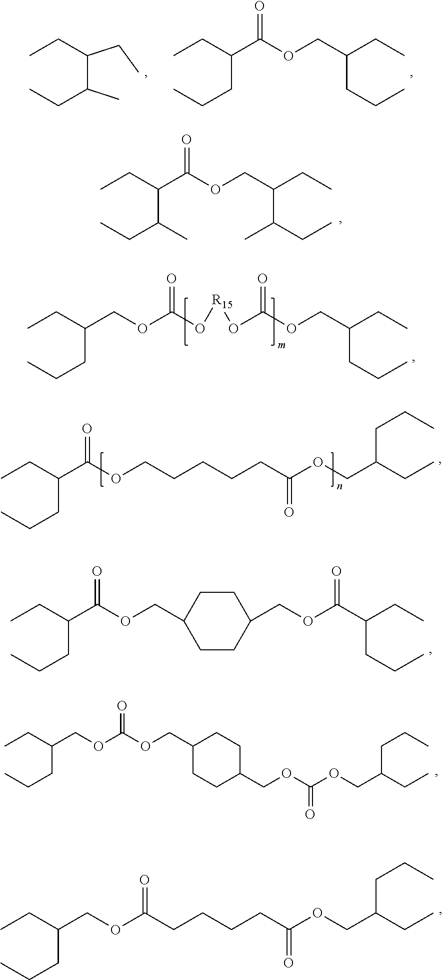

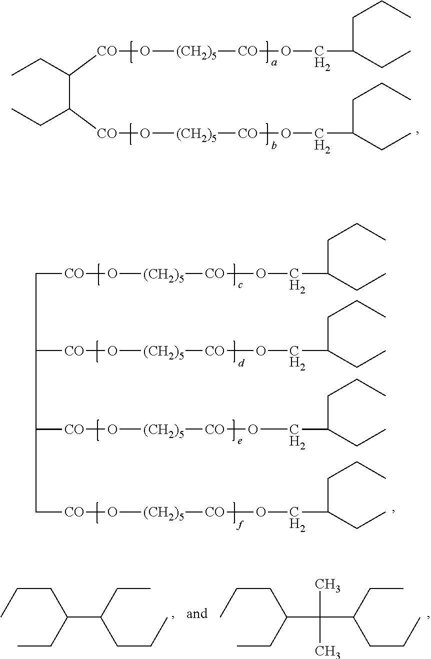

wherein R₁₅ is an alkyl chain having a carbon number of 2 to 18, the alkyl chain may be a straight chain, a branched chain, or a chain having cyclic skeleton, and wherein m and n are independently integer number of 1 to 30, and a, b, c, d, e and f are independently integer number of 0 to 30.
[d10] The process according to any one of [d1] to [d9], wherein the multifunctional epoxide is

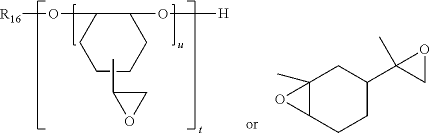

wherein R₁₆ is an alkyl chain having a carbon number of 2 to 18, the alkyl chain may be a straight chain, a branched chain, or a chain having cyclic skeleton, and wherein t and u are independently integer number of 1 to 30.
[d11] The solution according to any one of [d1] to [d10], wherein the multifunctional epoxide is selected from the group of phenolic epoxides and cyclic aliphatic epoxides.
[d12] The process according to any one of [d1] to [d11], wherein the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate.
[d13] The process according to any one of [d1] to [d12], wherein the amount of multifunctional epoxide is approximately 2 to 10% of the weight of the polyamide.
[d14] The process according to any one of [d1] to [d13], wherein the solvent is a polar solvent or a mixed solvent comprising one or more polar solvents.
[d15] The process according to any one of [d1] to[d14], wherein the solvent is an organic and/or an inorganic solvent.
[d16] The process according to any one of [d1] to [d15], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[d17] The process according to any one of [d1] to [d16] wherein the heating step is carried out under reduced pressure or an inert atmosphere, the temperature is less than 300° C., and the heating time 5 is more than approximately 1 minute.
[d18] The process according to any one of [d1] to [d16], wherein the temperature is between approximately 200° C. and approximately 250° C.
[d19] The process according to any one of [d1] to [d18], wherein the heating time is more than approximately 1 minute and less than approximately 30 minutes.
[d20] The process according to any one of [d1] to [d19], wherein the polyamide is first isolated from the polyamide solution by precipitation and redissolved in a solvent prior to the addition of the multifunctional epoxy compound.
[d21] The process according to any one of [d1] to [d20], wherein the film is produced in the absence of inorganic salt.
[d22] The process according to any one of [d1] to [d21], further comprising the step of:

h) de-bonding, from the base, the display element, the optical element or the illumination element formed on the base.
[e1] A process for manufacturing a transparent, solvent resistant, dimensionally stable, aromatic polyamide film comprising the steps of:

a) forming a mixture of two or more aromatic diamines where at least one of the diamines contains one or more functional groups that can react with an epoxy group.

b) dissolving the aromatic diamine mixture in a polar solvent;

c) reacting the diamine mixture with at least one aromatic diacid dichloride, wherein hydrochloric acid and a polyamide solution is generated;

d) simultaneously removing the free hydrochloric acid by reaction with an acid trapping reagent;

e) adding a multifunctional epoxide;

f) casting the resulting polyamide solution into a film at a temperature below approximately 200° C.;

g) heating the polyamide film at a temperature that results is the film becoming solvent resistant.
[e2] The process of [e1], wherein one of the aromatic diamines is selected from the group comprising 4,4′-diamino-2,2′-bistrifluoromethylbenzidine, 9,9-bis(4-aminophenyl)fluorine, and 9,9-bis(3-fluoro-4-aminophenyl)fluorine, 4,4′-diamino-2,2′-bistrifluoromethoxylbenzidine, 4,4′-diamino-2,2′-bistrifluoromethyldiphenyl ether, bis(4-amino-2-trifluoromethylphenyloxyl) benzene, and bis(4-amino-2-trifluoromethylphenyloxyl) biphenyl.
[e3] The process of [e1], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[e4] The process of [e1], wherein the polar solvent is N,N-dimethylacetamide.
[e5] The process of [e1], wherein the amount of diamine that contains one or more functional groups that can react with an epoxy group is greater than approximately one mol % to and less than approximately 10 mol % of the total diamine mixture.
[e6] The process of [e1] wherein the functional group of the aromatic diamine containing a functional group that can react with an epoxy group is a carboxyl group.
[e7] The process of [e6], wherein the diamine is 4,4′-diaminodiphenic acid or 3,5-diaminobenzoic acid.
[e8] The process of [e1], wherein the functional group of the aromatic diamine containing a functional group that can react with an epoxy group is a hydroxyl group.
[e9] The process of [e1], wherein the reaction of hydrochloric acid with the acid trapping reagent yields a volatile product and the film is cast directly from the reaction mixture.
[e10] The process of [e9], wherein the acid trapping reagent is propylene oxide.
[e11] The process of [e1], wherein the acid trapping reagent is an inorganic salt.
[e12] The process of [e1], wherein the multifunctional epoxide is selected from phenolic and cyclic aliphatic epoxides.
[e13] The process of [e1], wherein the multifunctional epoxide is selected from the group comprising diglycidyl 1,2-cyclohexanedicarboxylate, triglycidyl isocyanurate, tetraglycidyl 4,4′-diaminophenylmethane, 2,2-bis(4-glycidyloxylphenyl)propane and its higher molecular weight homologs, novolac epoxides, 7H-indeo[1,2-b:5,6-b′]bisoxireneoctahydro, and epoxycyclohexylmethyl 3,4-epoxycyclohexanecarboxylate.
[e14] The process of [e1], wherein the amount of multifunctional epoxide is approximately 2 to 10% of the weight of the polyamide.
[e15] The process of [e1], wherein the heating step is carried out under reduced pressure or an inert atmosphere, the temperature is less than 300° C., and the heating time is more than approximately 1 minute
[e16] The process of [e15], wherein the temperature is between approximately 200° C. and approximately 250° C.
[e17] The process of [e15], wherein the heating time is more than approximately 1 minute and less than approximately 30 minutes.
[e18] The process of [e1], wherein the polyamide is first isolated from the polyamide solution by precipitation and redissolved in a polar solvent prior to the addition of the multifunctional epoxy compound.
[e19] The process of [e1], wherein the polyamide film is produced in the absence of inorganic salt.
[e20] A transparent, solvent resistant, aromatic polyamide film produced in accordance with the process of [e1].
[e21] A transparent aromatic polyamide film comprising:

a) an aromatic polyamide having repeat units of general formulas (I) and (II):

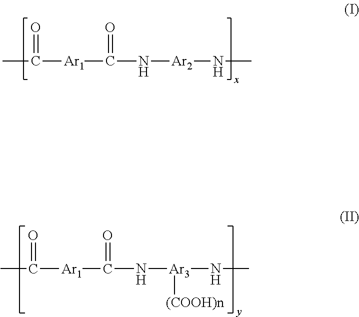

Wherein x=0.9 to 0.99 and y=0.1 to 0.01; wherein (I) and (II) are selected so that the polyamide is soluble in polar solvents and can be solution cast into a clear film; wherein n=1, 2; wherein Ar₁ is selected from the group comprising:

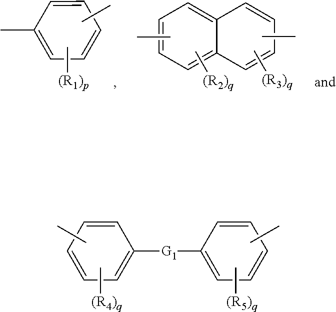

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of aromatic units which form diamines:

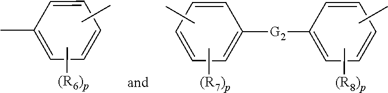

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₃ is selected from the group of aromatic units which form diamines containing a free carboxylic acid group:

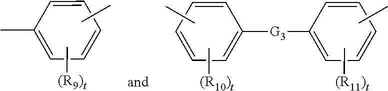

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.
and,

b) a multifunctional epoxide selected from the group with general structures (lll) and (lV):

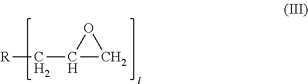

wherein l represents the number of glycidyl group, and R is selected from the group comprising:

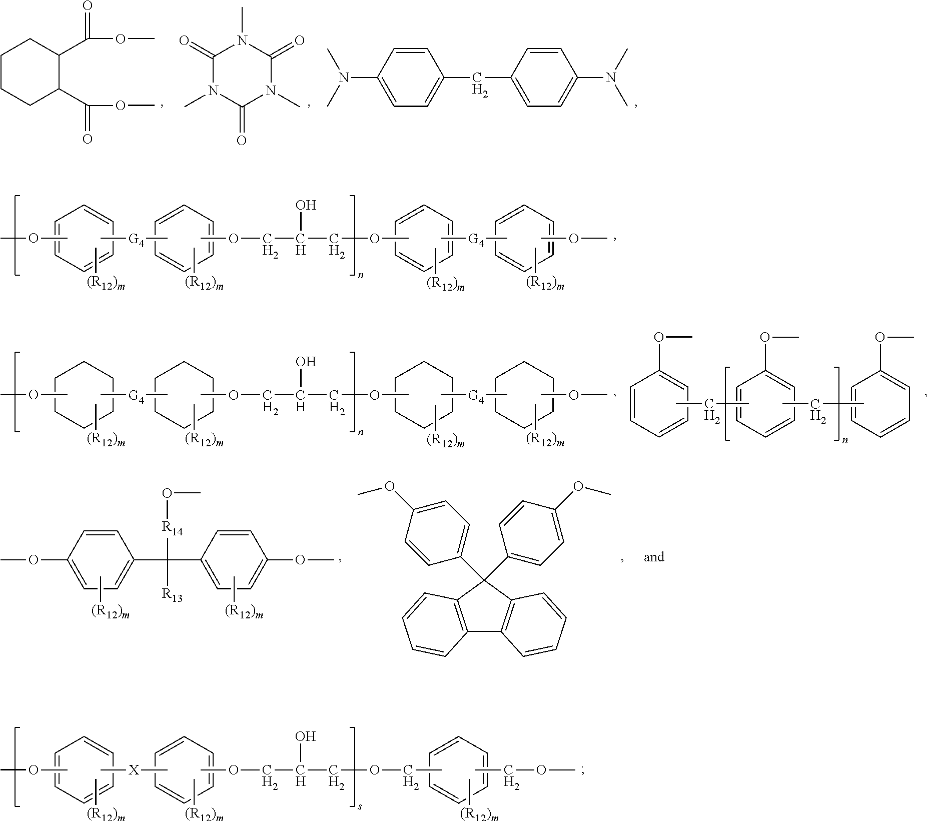

wherein m=1 to 4, and n and s are the average number of units and independently range from of 0 to 30;

wherein R₁₂s are same or different, and are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. G₄ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene, R₁₃ is a hydrogen or methyl group, and R₁₄ is a divalent organic group;

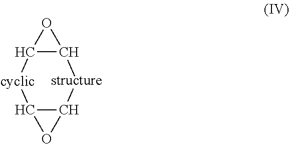

wherein the cyclic structure is selected from the group comprising:

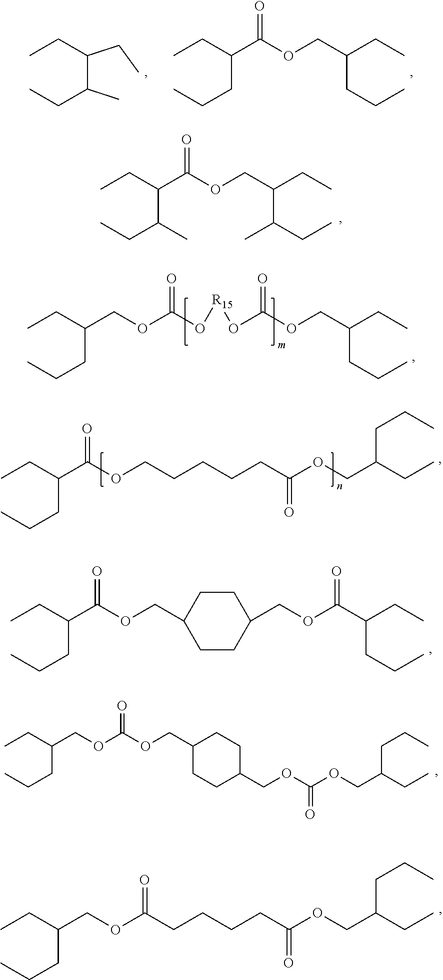

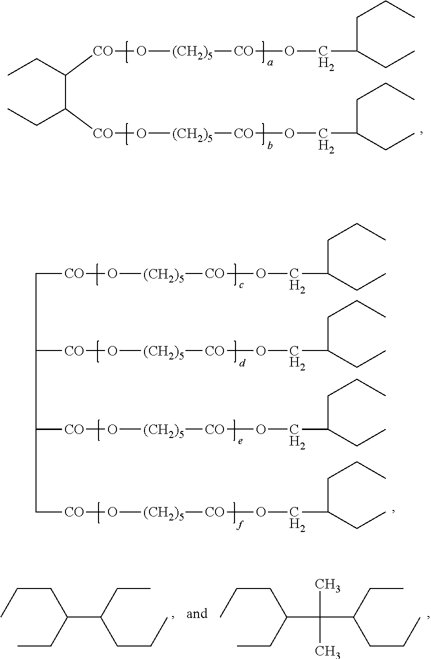

wherein R₁₅ is an alkyl chain having a carbon number of 2 to 18, the alkyl chain may be a straight chain, a branched chain, or a chain having cyclic skeleton, and wherein m and n are independently integer number of 1 to 30, and a, b, c, d, e and f are independently integer number of 0 to 30.
[e22] The film according to [e21], wherein the copolymer contains multiple repeat units with structures (I) and (II) where Ar₁, Ar₂, and Ar₃ are the same or different.
[e23] The film according to [e21], wherein the polyamide has a Tg >300 C
[e24] The film according to [e21], wherein the optical transmittance is greater than approximately 80% between 400 and 750 nm.
[e25] The film according to [e21], wherein the film is heated under reduced pressure or under an inert atmosphere at a temperature that results is the film becoming solvent resistant.
[e26] The film according to [e25], wherein heating is conducted below approximately 300° C. for at least approximately 1 minute.
[e27] The film according to [e26], wherein heating is conducted between approximately 200° C. and approximately 250° C. for at least approximately 1 minute
[e28] The film according to [e27], wherein heating is conducted for at least approximately 1 minute and less than approximately 30 minutes.
[e29] The film according to [e25], wherein the optical transmittance is greater than approximately 80% between 400 and 750 nm.
[e30] The film according to [e29], wherein the optical transmittance is greater than approximately 85% at 550 nm.
[e31] The film according to [e25], wherein the film thickness is greater than approximately 5 μm.
[e32] The film according to [e31], wherein the film thickness is between approximately 10 μm and approximately 100 μm.
[e33] The film according to [e25], wherein the film is adhered to a substrate and wherein the film thickness is greater than approximately 5 μm.
[e34] The film according to [e33], wherein the substrate is a glass film greater than approximately 50 μm thick.
[e35] The film according to [e25], wherein the average coefficient of thermal expansion is less than approximately 20 ppm/° C. between 25° C. and 250° C.
[e36] The film according to [e35], wherein the average coefficient of thermal expansion is less than approximately 10 ppm/° C. between 25° C. and 250° C.

### EXAMPLES

### Example 1

This example illustrates the general procedure for the preparation of a copolymer from TPC, IPC and PFMB (70%/30%/100% mol ratio) and 5% TG (weight ratio to the polymer) via solution condensation.

To a 250 ml three necked round bottom flask, equipped with a mechanical stirrer, a nitrogen inlet and outlet, are added PFMB (3.2024 g, 0.01 mol) and dried DMAc (45 ml). After the PFMB dissolved completely, IPC (0.6395 g 0.003 mol) was added to the solution, and the flask wall was washed with DMAc (1.5 ml). After 15 minutes, TPC (1.4211 g, 0.007 mol) was added to the solution and the flask wall was again washed with DMAc (1.5 ml). The solution becomes a gel. After adding PrO (1.4 g, 0.024 mol), the mixture returns to a viscous and homogenous solution. The reaction finishes within another 4 hours. After TG (0.45 g) was added, the mixture was stirred for another two hour. The resulting solution is ready to cast into film

### Example 2

This example illustrates the general procedure for the preparation of a solution containing a copolymer of TPC, IPC, DADP, and PFMB (70%/30%/3%/97% mol ratio) and 5 weight % via solution condensation.

To a 250 ml three necked round bottom flask, equipped with a mechanical stirrer, a nitrogen inlet and outlet, are added PFMB (3.1060 g, 0.0097 mol), DADP (0.0817 g, 0.0003 mol), and dried DMAc (45 ml). After the PFMB dissolved completely, IPC (0.6091 g 0.003 mol) was added to the solution, and the flask wall was washed with DMAc (1.5 ml). After 15 minutes, TPC (1.4211 g, 0.007 mol) is added to the solution and the flask wall was again washed with DMAc (1.5 ml). The solution becomes a gel. After adding PrO (1.4 g, 0.024 mol), the mixture returns to a viscous and homogenous solution. The reaction finishes within another 4 hours. After TG (0.45 g) was added, the mixture was stirred for another two hours. The resulting solution is ready to cast into film.

### Example 3

This example illustrates the general procedure for the preparation of a solution containing a copolymer of TPC, IPC, DAB, and PFMB (75%/25%/5%/95% mol ratio) and 5 weight % TG via solution condensation.

To a 250 ml three necked round bottom flask, equipped with a mechanical stirrer, a nitrogen inlet and outlet, are added PFMB (3.0423 g, 0.0095 mol), DAB (0.0761 g, 0.0005 mol), and dried DMAc (45 ml). After the PFMB dissolved completely, IPC (0.5076 g 0.0025 mol) was added to the solution, and the flask wall was washed with DMAc (1.5 ml). After 15 minutes, TPC (1.5227 g, 0.0075 mol) was added to the solution and the flask wall was again washed with DMAc (1.5 ml). The solution becomes a gel. After adding PrO (1.4 g, 0.024 mol), the mixture returns to a viscous and homogenous solution. The reaction finishes within another 4 hours. After TG (0.45 g) was added, the mixture was stirred for another two hour. The resulting solution is ready to cast into film.

### Example 4

This example illustrates the general procedure for the preparation of a solution containing a copolymer of TPC, IPC, DAB, and PFMB (75%/25%/5%/95% mol ratio), end-capped with benzoyl chloride and 5 weight % TG via solution condensation.

To a 250 ml three necked round bottom flask, equipped with a mechanical stirrer, a nitrogen inlet and outlet, are added PFMB (3.0423 g, 0.0095 mol), DAB (0.0761 g, 0.0005 mol), and dried DMAc (27 ml) and BCS (18 ml). After the PFMB and DAB dissolved completely, PrO (1.4 g, 0.024 mol) was added to the solution. Under stirring, IPC (0.4974 g 0.00245 mol) was added to the solution, and the flask wall was washed with DMAc (0.9 ml) and BCS (0.6 ml). After 15 minutes, TPC (1.5125 g, 0.00745 mol) was added to the solution and the flask wall was again washed with DMAc (0.9 ml) and BCS (0.6 ml). After two hours, benzoyl chloride (0.032 g, 0.23 mmol) was added to the solution and stirred to the solution and stirred for another two hours. After TG (0.45 g) was added, the mixture was stirred for another two hour. The resulting solution is ready to cast into film

### Comparative Example 1

The polymer was prepared according to the procedure described in Example 1 without the addition of TG.

### Comparative Example 2

The polymer was prepared according to the procedure described in Example 2 without the addition of TG.

### Comparative Example 3

The polymer was prepared according to the procedure described in Example 3 without the addition of TG.

### Example 5

This example illustrates the general procedure for the preparation of a solution containing a copolymer of TPC, IPC, DAB, and PFMB (10%/90%/5%/95% mol ratio), end-capped with benzoyl chloride and 5.8 weight % jER828 via solution condensation. The jER828 is a Bisphenol A epoxy resin (Mitsubishi Chemical) represented by the formula blow (n=0.19).

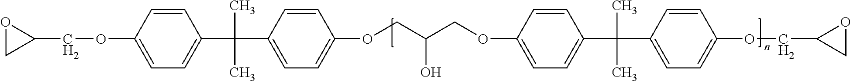

To a 250 ml three necked round bottom flask, equipped with a mechanical stirrer, a nitrogen inlet and outlet, are added PFMB (3.0423 g, 0.0095 mol), DAB (0.0761 g, 0.0005 mol), and dried DMAc (27 ml) and BCS (18 ml). After the PFMB and DAB dissolved completely, PrO (1.4 g, 0.024 mol) was added to the solution. Under stirring, IPC (1.817 g 0.00095 mol) was added to the solution, and the flask wall was washed with DMAc (0.9 ml) and BCS (0.6 ml). After 15 minutes, TPC (0.202 g, 0.000995 mol) was added to the solution and the flask wall was again washed with DMAc (0.9 ml) and BCS (0.6 ml). After two hours, benzoyl chloride (0.032 g, 0.23 mmol) was added to the solution and stirred to the solution and stirred for another two hours. Then an epoxy resin; jER828 (0.12 g) was added, and the mixture was stirred for another two hour. The resulting solution is ready to cast into film

### Example 6

This example illustrates the general procedure for the preparation of a solution containing a copolymer of TPC, IPC, DAB, and PFMB (10%/90%/5%/95% mol ratio), end-capped with benzoyl chloride and 6.2 weight % YX-8000 via solution condensation. The YX-8000 is a Hydrogenated Bisphenol A epoxy resin (Mitsubishi Chemical) represented by the formula blow (n=0.19).

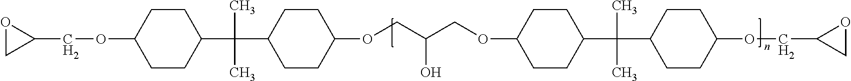

To a 250 ml three necked round bottom flask, equipped with a mechanical stirrer, a nitrogen inlet and outlet, are added PFMB (3.0423 g, 0.0095 mol), DAB (0.0761 g, 0.0005 mol), and dried DMAc (27 ml) and BCS (18 ml). After the PFMB and DAB dissolved completely, PrO (1.4 g, 0.024 mol) was added to the solution. Under stirring, IPC (1.817 g 0.00095 mol) was added to the solution, and the flask wall was washed with DMAc (0.9 ml) and BCS (0.6 ml). After 15 minutes, TPC (0.202 g, 0.000995 mol) was added to the solution and the flask wall was again washed with DMAc (0.9 ml) and BCS (0.6 ml). After two hours, benzoyl chloride (0.032 g, 0.23 mmol) was added to the solution and stirred to the solution and stirred for another two hours. Then an epoxy resin; YX-8000 (0.125 g) was added, and the mixture was stirred for another two hour. The resulting solution is ready to cast into film

### Example 7

This example illustrates the general procedure for the preparation of a solution containing a copolymer of TPC, IPC, DAB, and PFMB (10%/90%/5%/95% mol ratio), end-capped with benzoyl chloride and 2.7 weight % Celloxide8000 via solution condensation. The Celloxide8000 is a (3,3′,4,4′-diepoxy) bicyclohexyl (Mitsubishi Chemica) represented by the formula blow.

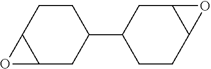 [SMILES: C1CC2OC2CC1C1CCC2OC2C1]

To a 250 ml three necked round bottom flask, equipped with a mechanical stirrer, a nitrogen inlet and outlet, are added PFMB (3.0423 g, 0.0095 mol), DAB (0.0761 g, 0.0005 mol), and dried DMAc (27 ml) and BCS (18 ml). After the PFMB and DAB dissolved completely, PrO (1.4 g, 0.024 mol) was added to the solution. Under stirring, IPC (1.817 g 0.00095 mol) was added to the solution, and the flask wall was washed with DMAc (0.9 ml) and BCS (0.6 ml). After 15 minutes, TPC (0.202 g, 0.000995 mol) was added to the solution and the flask wall was again washed with DMAc (0.9 ml) and BCS (0.6 ml). After two hours, benzoyl chloride (0.032 g, 0.23 mmol) was added to the solution and stirred to the solution and stirred for another two hours. Then an epoxy resin; Celloxide8000 (0.055 g) was added, and the mixture was stirred for another two hour. The resulting solution is ready to cast into film.

### Comparative Example 4

The polymer was prepared according to the procedure described in Example 5 without the addition of jER828.

### Preparation and Characterization of the Polymer Films

The polymer solution is used directly for the film casting after polymerization. The solids content and viscosity of the polymer solution can be adjusted during the polymerization. For the preparation of small films, the solution is poured on a flat glass plate and the film thickness is adjusted by a doctor blade. After drying on glass, under reduced pressure, at 60° C. for several hours, the on-glass film is further dried at 200° C. under protection of dry nitrogen flow for 1 hour. The film is cured by heating at a temperature between approximately 200° C. and approximately 250° C. under vacuum or in an inert atmosphere. The film can also be produced continuously by a roll-to-roll process.

In one embodiment of this disclosure, the polymer solution may be solution cast onto a reinforcing substrate like thin glass, silica or a microelectronic device. In this case, the process is adjusted so that the final polyamide film thickness is greater than approximately 5 μm. The film is used in place and not removed from the substrate in free standing form.

The CTE and Tg were measured with a thermal mechanical analyzer (TA Q 400 TMA). The sample film has a thickness around 20 μm, and the load strain is 0.05N. In one embodiment, the CTE is less than approximately 20 ppm/° C., but it is understood that in other embodiments, the CTE is less than approximately 15 ppm/° C., less than approximately 10 ppm/° C., and less than approximately 5 ppm/° C. It is to be understood that within these embodiments the CTE can be less than approximately 19, 18, 17, 16, 15, 14, 13, 12, 11, 10, 9, 8, 7, 6, or 5 ppm/° C. The experimentally derived CTEs are the average of the CTE obtained from the room temperature to about 250° C.

Film transparency is measured by determining the transmittance of a 10 μm thick film from 400 to 750 nm with a UV-Visible spectrometer (Shimadzu UV 2450).

The solvent resistance of the film is determined by immersing it in a selected solvent (N-methyl-2-pyrrolidinone) for 30 minutes at room temperature. The film is considered solvent resistant if it is substantially free of surface wrinkles, swelling, or any other visible damage after immersion. The films are useful as substrates for flexible electronic devices.

The curing conditions used for the example copolyamides and the properties of their crosslinked films are shown in Tables 1 and 2. The Tables' data illustrate the relative mild curing conditions and the beneficial effects of free pendant carboxyl groups on the polyamide and epoxy groups on the curing process.

TABLE 1
Curing Conditions and Film Properties

| | | | | | Comparative | Comparative | Comparative |
|---|---|---|---|---|---|---|---|
| | Example 1 | Example 2 | Example 3 | Example 4 | Example 1 | Example 2 | Example 3 |
| Curing | 250° C. × | 240° C. × | 220° C. × | 220° C. × | Cannot be | 330° C. × | 330° C. × |
| conditions | 10 minute | 5 minute | 5 minute | 5 minute | cured | 5 minute | 10 minute |
| Tg (° C.) | 325 | 327 | 335 | 320 | 336 | 334 | 350 |
| CTE | 4.0 | 6.2 | 4.6 | 5.1 | 7.4 | 7.0 | 12.0 |
| (ppm/° C.) | | | | | | | |
| T % at | 82 | 83 | 83 | 83 | 82 | 80 | 81 |
| 400 nm | | | | | | | |
| Solvent | Yes | Yes | Yes | Yes | No | Yes | Yes |
| resistance | (A) | (A) | (A) | (A) | (C) | (A) | (A) |
| (rating) | | | | | | | |

[rating]
A: not dissolved, and not swelled in solvent
B: not dissolved, and swelled in solvent
C: dissolved in solvent

TABLE 2
Curing Conditions and Film Properties

| | | | | Comparative |
|---|---|---|---|---|
| | Example 5 | Example 6 | Example 7 | Example 4 |
| Curing | 280° C. × | 280° C. × | 280° C. × | 280° C. × |
| conditions | 30 minutes | 30 minutes | 30 minutes | 30 minutes |
| Tg (° C.) | — | — | — | — |
| CTE | 9.7 | 8.9 | 9.9 | 8.5 |
| (ppm/° C.) | | | | |
| T % at | 80 | 79 | 80 | 81 |
| 400 nm | | | | |
| Solvent | Yes | Yes | Yes | No |
| resistance | (A) | (A) | (B) | (C) |
| (rating) | | | | |

[rating]
A: not dissolved, and not swelled in solvent
B: not dissolved, and swelled in solvent
C: dissolved in solvent

The embodiments have been described, hereinabove. It will be apparent to those skilled in the art that the above methods and apparatuses may incorporate changes and modifications without departing from the general scope of this disclosure. It is intended to include all such modifications and alterations insofar as they come within the scope of the appended claims or the equivalents thereof. Although the description above contains much specificity, this should not be construed as limiting the scope of the disclosure, but as merely providing illustrations of some of the embodiments of this disclosure. Various other embodiments and ramifications are possible within its scope.

Furthermore, notwithstanding that the numerical ranges and parameters setting forth the broad scope of the disclosure are approximations, the numerical values set forth in the specific examples are reported as precisely as possible. Any numerical value, however, inherently contain certain errors necessarily resulting from the standard deviation found in their respective testing measurements.

What is claimed is:

1. A process for manufacturing a display device, an optical device or an illuminating device, comprising:
casting a polyamide solution onto a base at a temperature below 200° C. to obtain a film;
heating the film on the base at a temperature sufficient to make the film solvent resistant and obtain a polyamide film;
forming on a surface of the polyamide film one of a display element, an optical element and an illumination element to form a display device, an optical device or an illumination device; and
de-bonding the base from the display device, the optical device or the illuminating device,
wherein the polyamide solution comprises a solvent, an aromatic polyamide dissolved in the solvent, and a multifunctional epoxyde, where the aromatic polyamide comprises at least one functional group that reacts with an epoxy group, the aromatic polyamide comprises a first repeat unit of formula (I) and a second repeat unit of formula (II) 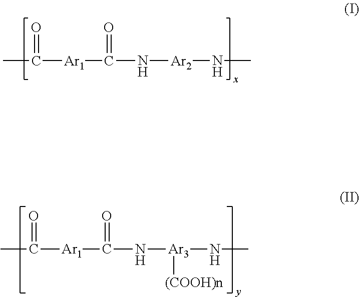
where x represents mole % of the first repeat unit, y represents mole % of the second repeat unit, x varies from 90 to 99, y varies from 10 to 1, n=1 to 4, Ar₁ is selected from the group consisting of 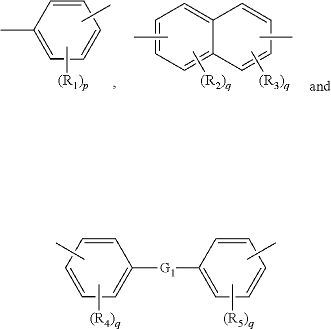
where p=4, q=3, and R₁, R₂, R₃, R₄, and R₅ are at least one selected from the group consisting of hydrogen, halogen, alkyl, substituted alkyl, nitro, cyano, thioalkyl, alkoxy, substituted alkoxy, aryl, or substituted aryl, alkyl ester and substituted alkyl esters, and a combination thereof, G₁ is selected from the group consisting of a covalent bond, a CH₂ group, a C(CH₃)₂ group, a C(CX₃)₂ group where X is a halogen, a CO group, an O atom, a S atom, a SO₂ group, a Si(CH₃)₂ group, 9,9-fluorene group, substituted 9,9-fluorene, and an OZO group where Z is a aryl group or substituted aryl group, Ar₂ is selected from the group of consisting of 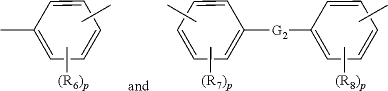
where p=4, R₆, R₇, and R₈ are selected from the group consisting of hydrogen, halogen, alkyl, substituted alkyl, nitro, cyano, thioalkyl, alkoxy, substituted alkoxy, aryl, substituted aryl, alkyl ester, and substituted alkyl esters, G₂ is selected from the group consisting of a covalent bond, a CH₂ group, a C(CH₃)₂ group, a C(CX₃)₂ group where X is a halogen, a CO group, an O atom, a S atom, a SO₂ group, a Si(CH₃)₂ group, 9,9-fluorene group, substituted 9,9-fluorene, and an OZO group where Z is a aryl group or substituted aryl group, Ar₃ is selected from the group consisting of 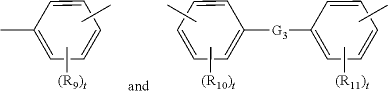
where t=2 or 3, R₉, R₁₀, and R₁₁ are selected from the group consisting of hydrogen, halogen, alkyl, substituted alkyl, nitro, cyano, thioalkyl, alkoxy, substituted alkoxy, aryl, substituted aryl, alkyl ester, and substituted alkyl esters, G₃ is selected from the group consisting of a covalent bond, a CH₂ group, a C(CH₃)₂ group, a C(CX₃)₂ group where X is a halogen, a CO group, an O atom, a S atom, a SO₂ group, a Si(CH₃)₂ group, 9,9-fluorene group, substituted 9,9-fluorene, and an OZO group where Z is a aryl group or substituted aryl group.

2. The process according to claim 1, wherein the heating of the film is conducted at a temperature in a range of 200° C. to 300° C.

3. The process according to claim 1, wherein the de-bonding comprises using a de-bonding layer, irradiating a laser, or heating the base.

4. The process according to claim 1, wherein the multifunctional epoxide has one of a structure (III) and a structure (IV), the structure (III) is 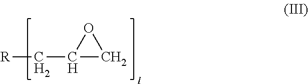
where l represents the number of glycidyl group, and R is one selected from the group consisting of 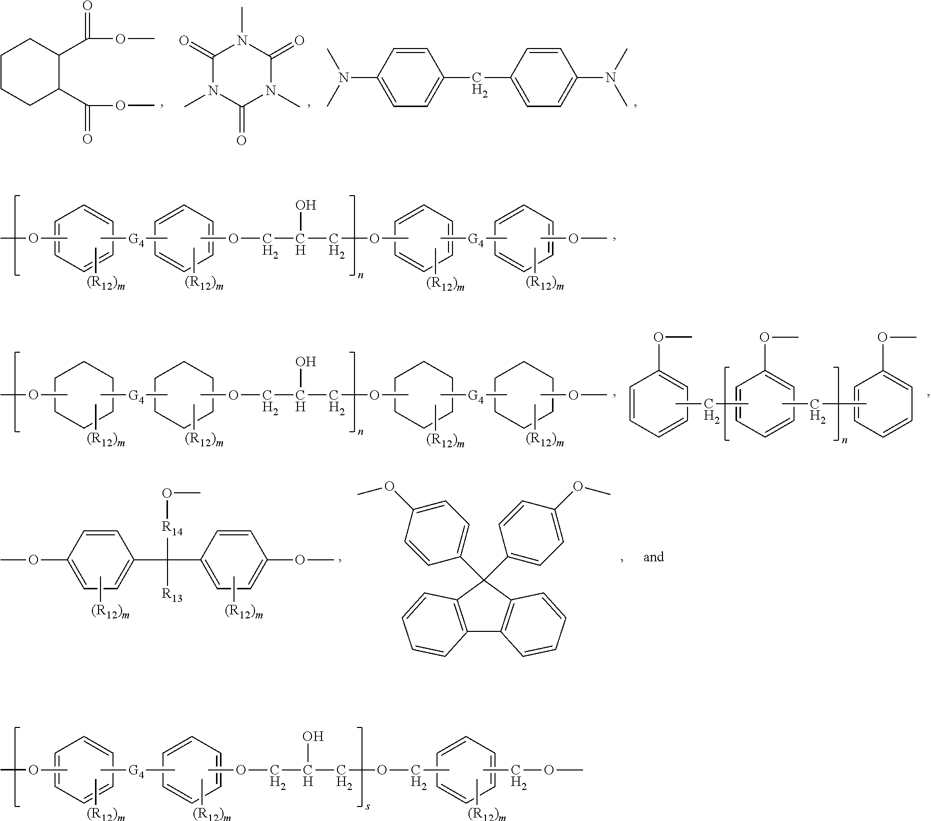
where m=1 to 4, n and s are the average number of units and independently range from of 0 to 30, R₁₂s are same or different, and are at least one selected from the group consisting of hydrogen, halogen, alkyl, substituted alkyl, nitro, cyano, thioalkyl, alkoxy, substituted alkoxy, aryl, substituted aryl, alkyl ester, and substituted alkyl esters, G₄ is one selected from the group consisting of a covalent bond, a CH₂ group, a C(CH₃)₂ group, a C(CX₃)₂ group where X is a halogen, a CO group, an O atom, a S atom, a SO₂ group, a Si(CH₃)₂ group, 9,9-fluorene group, substituted 9,9-fluorene, and an OZO group where Z is a aryl group or substituted aryl group, R₁₃ is a hydrogen or methyl group, and R₁₄ is a divalent organic group, and the structure (IV) is 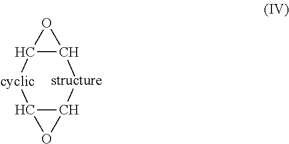
where the cyclic structure is a structure selected from the group consisting of 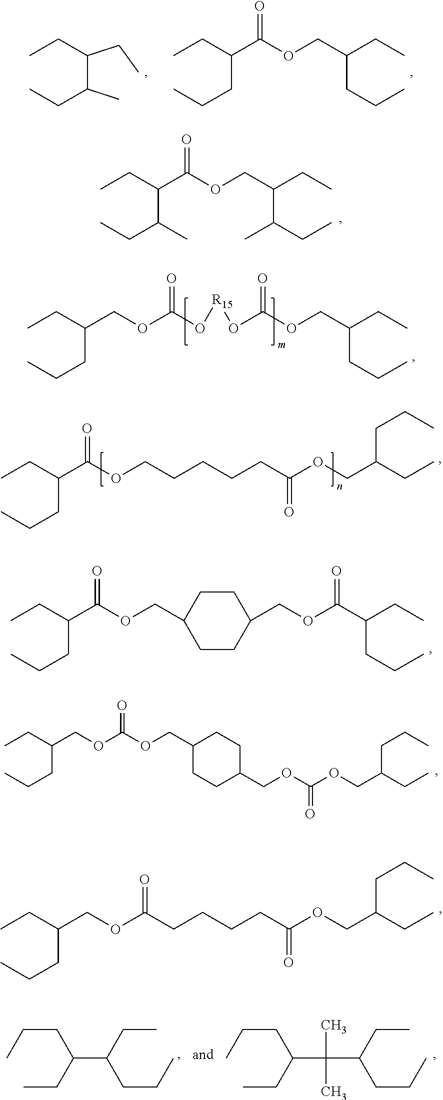
where R₁₅ is an alkyl chain having a carbon number of 2 to 18, the alkyl chain is a straight chain, a branched chain, or a chain having cyclic skeleton, m and n are independently integer number of 1 to 30, and a, b, c, d, e and f are independently integer number of 0 to 30.

5. The process according to claim 1, wherein the multifunctional epoxide is 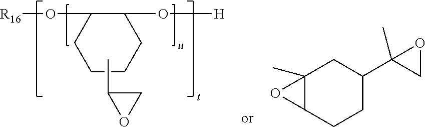
where R₁₆ is an alkyl chain having a carbon number of 2 to 18, the alkyl chain is a straight chain, a branched chain, or a chain having cyclic skeleton, and t and u are independently integer number of 1 to 30.

6. The process according to claim 1, wherein the solvent is a polar solvent or a mixed solvent comprising at least one polar solvent.

7. The process according to claim 1, wherein the solvent is cresol, N,N-dimethylacetamide, N-methyl-2-pyrrolidinone, dimethylsulfoxide, butyl cellosolve, or a mixed solvent comprising at least one of cresol, N,N-dimethylacetamide, N-methyl-2-pyrrolidinone, dimethylsulfoxide, 1,3-dimethyl-imidazolidinone, and butyl cellosolve.

8. The process according to claim 1, wherein the polyamide solution is obtained by a process comprising:
dissolving at least one aromatic diamine in a solvent such that at least one of aromatic diamines has at least one functional group which reacts with an epoxy group;
adding at least one aromatic diacid dichloride to a mixture comprising the solvent and at least one aromatic diamine such that the aromatic diacid dichloride and the aromatic diamine or diamines polymerize and generate hydrochloric acid and a polyamide solution is obtained;
adding an acid trapping reagent to the polyamide solution such that the hydrochloric acid is removed by reaction with the acid trapping reagent; and
adding a multifunctional epoxide to the polyamide solution.

9. The process according to claim 8, wherein the acid trapping reagent is propylene oxide.

10. The process according to claim 2, wherein the de-bonding comprises using a de-bonding layer, irradiating a laser, or heating the base.

11. The process according to claim 2, wherein the multifunctional epoxide has one of a structure (III) and a structure (IV), the structure (III) is 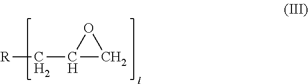
where l represents the number of glycidyl group, and R is one selected from the group consisting of 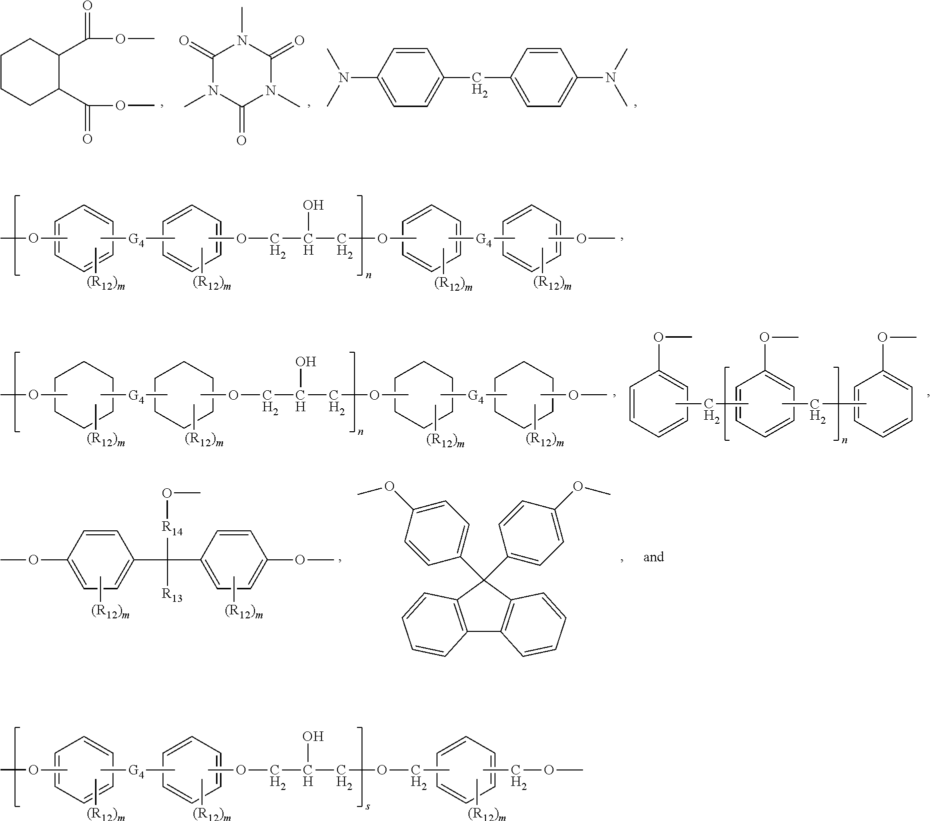
where m=1 to 4, n and s are the average number of units and independently range from of 0 to 30, R₁₂s are same or different, and are at least one selected from the group consisting of hydrogen, halogen, alkyl, substituted alkyl, nitro, cyano, thioalkyl, alkoxy, substituted alkoxy, aryl, substituted aryl, alkyl ester, and substituted alkyl esters, G₄ is one selected from the group consisting of a covalent bond, a CH₂ group, a C(CH₃)₂ group, a C(CX₃)₂ group where X is a halogen, a CO group, an O atom, a S atom, a SO₂ group, a Si(CH₃)₂ group, 9,9-fluorene group, substituted 9,9-fluorene, and an OZO group where Z is a aryl group or substituted aryl group, R₁₃ is a hydrogen or methyl group, and R₁₄ is a divalent organic group, and the structure (IV) is 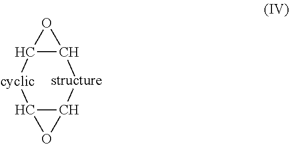
where the cyclic structure is a structure selected from the group consisting of 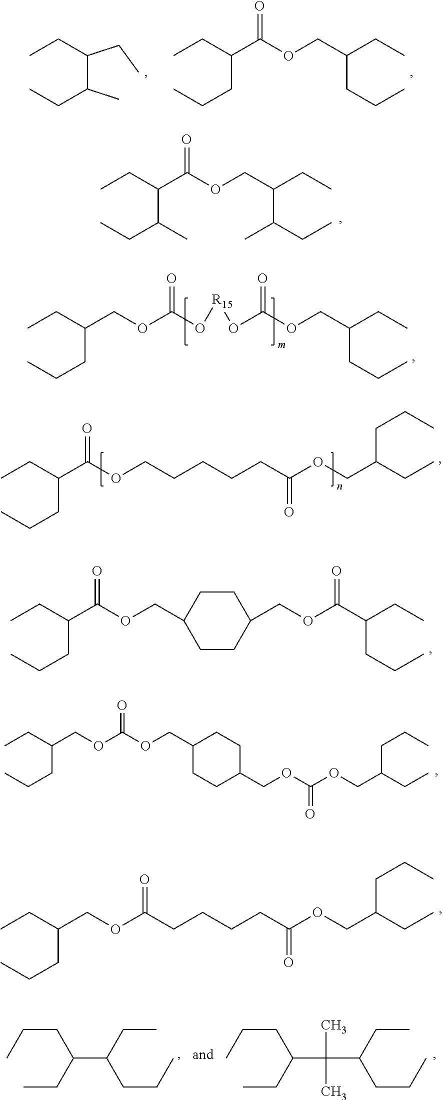
where R₁₅ is an alkyl chain having a carbon number of 2 to 18, the alkyl chain is a straight chain, a branched chain, or a chain having cyclic skeleton, m and n are independently integer number of 1 to 30, and a, b, c, d, e and f are independently integer number of 0 to 30.

12. The process according to claim 2, wherein the multifunctional epoxide is 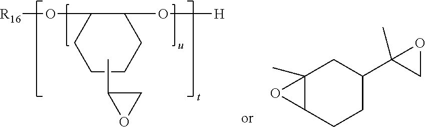
where R₁₆ is an alkyl chain having a carbon number of 2 to 18, the alkyl chain is a straight chain, a branched chain, or a chain having cyclic skeleton, and t and u are independently integer number of 1 to 30.

13. The process according to claim 2, wherein the solvent is a polar solvent or a mixed solvent comprising at least one polar solvent.

14. The process according to claim 2, wherein the solvent is cresol, N,N-dimethylacetamide, N-methyl-2-pyrrolidinone, dimethylsulfoxide, butyl cellosolve, or a mixed solvent comprising at least one of cresol, N,N-dimethylacetamide, N-methyl-2-pyrrolidinone, dimethylsulfoxide, 1,3-dimethyl-imidazolidinone, and butyl cellosolve.

15. The process according to claim 2, wherein the polyamide solution is obtained by a process comprising:
dissolving at least one aromatic diamine in a solvent such that at least one of aromatic diamines has at least one functional group which reacts with an epoxy group;
adding at least one aromatic diacid dichloride to a mixture comprising the solvent and at least one aromatic diamine such that the aromatic diacid dichloride and the aromatic diamine or diamines polymerize and generate hydrochloric acid and a polyamide solution is obtained;
adding an acid trapping reagent to the polyamide solution such that the hydrochloric acid is removed by reaction with the acid trapping reagent; and
adding a multifunctional epoxide to the polyamide solution.

16. The process according to claim 15, wherein the acid trapping reagent is propylene oxide.

17. The process according to claim 4, wherein the solvent is a polar solvent or a mixed solvent comprising at least one polar solvent.

18. The process according to claim 4, wherein the solvent is cresol, N,N-dimethylacetamide, N-methyl-2-pyrrolidinone, dimethylsulfoxide, butyl cellosolve, or a mixed solvent comprising at least one of cresol, N,N-dimethylacetamide, N-methyl-2-pyrrolidinone, dimethylsulfoxide, 1,3-dimethyl-imidazolidinone, and butyl cellosolve.

19. The process according to claim 4, wherein the polyamide solution is obtained by a process comprising:
dissolving at least one aromatic diamine in a solvent such that at least one of aromatic diamines has at least one functional group which reacts with an epoxy group;
adding at least one aromatic diacid dichloride to a mixture comprising the solvent and at least one aromatic diamine such that the aromatic diacid dichloride and the aromatic diamine or diamines polymerize and generate hydrochloric acid and a polyamide solution is obtained;
adding an acid trapping reagent to the polyamide solution such that the hydrochloric acid is removed by reaction with the acid trapping reagent; and
adding a multifunctional epoxide to the polyamide solution.

20. The process according to claim 19, wherein the acid trapping reagent is propylene oxide.
